(19) United States
(12) Patent Application Publication
(10) Pub. No.: US 2004/0056915 A1
(43) Pub. Date: Mar. 25, 2004

(54) Material arranging method, film-forming apparatus, electronic device and manufacturing method thereof, electro-optical device and manufacturing method thereof, and electronic apparatus

(75) Inventor: Takashi Miyazawa, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/630,864

(22) Filed: Jul. 31, 2003

(30) Foreign Application Priority Data
Aug. 2, 2002 (JP) 2002-226071

(51) Int. Cl. B41J 29/393

(52) U.S. Cl. 347/19; 347/101

(57) ABSTRACT

To provide a material arranging method, a film-forming apparatus, an electro-optical device and a manufacturing method thereof, an electronic device, and an electronic apparatus, capable of rapidly detecting a ejection failure of a nozzle, accomplishing reduction of defectives, and always stabilizing a state in which material is ejected. A film-forming apparatus according to the present invention comprises a pressure control system 12 for controlling the pressure in a vacuum chamber (processing chamber) 11 to a low pressure, at least one nozzle 15 for arranging material on a base (member) 14, a base stage 13 for holding the base 14, a driving system (moving means) 17 for relatively moving a position of the nozzle 15 or the base stage 13, and a detecting system (inspecting means) 19 for inspecting the material arranged on the base 14.

### BACKGROUND OF THE INVENTION

1. Field of Invention

The present invention relates to a material arranging method, a film-forming apparatus, an electronic device and a manufacturing method thereof, an electro-optical device and a manufacturing method thereof, and an electronic apparatus.

2. Description of Related Art

Developments of electro-optical devices used as displays or display light sources or the like and electronic devices such as semiconductor devices, etc. becomes faster every day. Film forming technologies and wiring technologies for specifically arranging a material in a predetermined position on a base are indispensable for the course of manufacturing the electro-optical devices and the electronic devices, and technologies for satisfying various manufacturing conditions such as accuracy, quality, manufacturing cost or the like have been requested.

The material arranging technologies can include a mask deposition method, a material ejection method (inkjet method), a printing method or the like, but recently, in order to provide specific functions on a film to be formed on a base, the diversification of materials to be arranged on the base proceeds and the development of the material arranging technologies having a high degree of freedom in selection of material proceeds.

For example, in a specification of Japanese Patent Application No. 2001-277102, a material arranging method, a film-forming apparatus, an electro-optical device and a manufacturing method thereof, an electronic device, and an electronic apparatus are disclosed. Specifically, the material arranging method disclosed in the specification is a method of arranging a material supplied from a nozzle in a predetermined position on a base, wherein inside of a processing chamber in which the base is provided is controlled to a pressure lower than inside of the nozzle and the material is discharged from the nozzle toward the base within the processing chamber of which the pressure is controlled.

According to the material arranging method described above, since the inside of the processing chamber in which the base is provided is controlled to a pressure lower than the inside of the nozzle and the material is discharged from the nozzle toward the base within the processing chamber of which the pressure is controlled, movement of the material supplied into the processing chamber can be promoted by means of the pressure difference to arrange the material on the base.

Further, by lowering the pressure within the processing chamber to a vacuum pressure, a material which is in a solid state under the atmospheric pressure can be converted into a liquid or gas state in the processing chamber, and as a result, the movement of the material can be facilitated. Therefore, the degree of freedom in selection of material is increased, and for example, a material having a low solubility can be arranged on a substrate without dissolving the material in a solvent.

However, in the conventional material arranging method, the nozzle may not eject the material accidentally or by means of sticking or crystallization of the material in the nozzle, and in this case, the producing processes are necessary to be restored into a normal state, by rapidly performing exchange of the nozzle or cleaning of the nozzle. At that time, conventionally, the generated defective substrate is all abandoned, or if it is multi-plane substrate, is partially abandoned.

Further, recently, for the purpose of good production efficiency, the scale-up of substrate proceeds, and for example, considering that a plurality of substrates is mainly acquired from a substrate having a shape of 730 mm×920 mm or a substrate of which one side exceeds 1 m, when the failure such as non-ejection of material occurs in a first sheet of region of product substrate shapes in the substrate, many defectives can be generated. That is, for the reason of decrease of production yield due to manufacturing of the electro-optical device or the electronic device having a defective, there is a problem that the cost merit according to the material arranging method described above cannot be sufficiently utilized.

Furthermore, even if the nozzle does not cause the non-ejection of material, when the ejection of material is rested for a predetermined time and then is re-started, there is a problem in that the amount of material to be ejected is not stabilized right after restarting of the ejection of material. For example, when a light-emitting layer is formed in manufacturing an organic electroluminescent (hereinafter, denoted as organic EL) element, a non-uniform light-emitting layer may be formed to cause non-uniformity in luminescence, and when various wires are formed in manufacturing a thin film transistor, the wires having a width of a desired high accuracy cannot be formed to cause a breaking of wires.

An object of the present invention is to provide a material arranging method, a film-forming apparatus, an electronic device and a manufacturing method thereof, an electro-optical device and a manufacturing method thereof, and an electronic apparatus, capable of accomplishing decrease of defectives by rapidly detecting the ejection failure of nozzles and always stabilizing the ejecting conditions of material.

### SUMMARY OF THE INVENTION

In order to solve the above problems, a material arranging method according to the present invention is a material arranging method of arranging a material on a base, the method comprising: an ejection step of ejecting the material from at least one nozzle toward a predetermined area of the base, which is provided in a vacuum atmosphere that is adjusted to a high degree of vacuum; and a detection step of detecting an ejection failure of a nozzle in the vacuum atmosphere before starting the ejection step.

According to the aforementioned method, by ejecting the material from at least one nozzle toward a predetermined area of the base, which is provided in a vacuum atmosphere that is adjusted to a high degree of vacuum, movement of the material is promoted by use of the pressure difference between the inside of the nozzle and the atmospheres in which the base is provided, and it is thus possible to arrange the material on the base. Furthermore, by making the place in which the base is provided to the vacuum atmosphere, a material which is in a solid state under the atmospheric pressure can be converted into a liquid or gas state in arrangement on the base, and as a result, the movement of material can be facilitated. For this reason, in the material arranging method, the degree of freedom in selection of material is increased, and for example, a material having a low solubility can be arranged on a substrate without dissolving the material in a solvent.

Furthermore, it is possible to arrange various materials such as high-molecular materials or low-molecular materials on the base, and also, by avoiding use of solvent or decreasing use amount of solvent, it is possible to avoid disadvantages such as deterioration of materials due to residual of solvent. Furthermore, by controlling the pressure of vacuum atmosphere, it is possible to discharge materials at molecular level from the nozzles, and as a result, it is possible to form a material film having much higher purity or control thickness of the material film with a high accuracy. Furthermore, by discharging the materials at a molecular level, it is facilitated to concurrently discharge a plurality of materials and mix them, and thus it is possible to form a functional film having a specific function on the base.

Furthermore, in the material arranging method, since the ejection failure of a nozzle is detected in the vacuum atmosphere before starting the ejection step, the ejection failure of the nozzle can be rapidly detected, and thus it is possible to accomplish decrease of defectives and to always stabilize the ejection condition of material. That is, by performing the detection of the ejection failure of the nozzle before arranging the material in a patterning area on the base, the plurality of defectives are prevented from being manufactured, so that it is possible to enhance the production yield of products.

Furthermore, in the material arranging method, it is preferable that the vacuum atmosphere be adjusted to a degree of vacuum of 10⁻³ torr (1.33322×10⁻¹ Pa) or less, and it is more preferable that the vacuum atmosphere be adjusted to a degree of vacuum of 10⁻⁵ torr (1.33322×10⁻³ Pa) or less.

By adjusting the vacuum atmosphere to 10⁻³ torr or less, a material whose ejection from the nozzle is difficult under the atmospheric pressure can be easily ejected from the nozzle, and by adjusting the vacuum atmosphere to 10⁻⁵ torr or less, it is possible to eject more kinds of materials and also to gasify the material to be ejected for facilitating the ejection.

Furthermore, in the material arranging method, the detection step may include an action of ejecting the material to a preliminary-ejecting area other than the predetermined area and detecting an ejection failure of a nozzle on the basis of the ejecting result. Furthermore, the detection step may include an action of providing a preliminary member in the predetermined area, ejecting the material to a preliminary-ejecting area provided in the preliminary member and detecting the ejection failure of the nozzle on the basis of the ejection result.

According to this method, by ejecting the material to the preliminary-ejecting area and detecting the ejection failure of the nozzle on the basis of the ejecting result, it is possible to surely reproduce in advance the ejecting conditions of the material to be arranged in the predetermined area on the base, and thus the ejection failure can be more accurately detected.

Furthermore, in the material arranging method, the detection of the ejection failure of the nozzle can be performed by means of spectroscopic means such as detecting light-reflectivity of the material ejected to the preliminary-ejecting area or detecting light-transmissivity.

By doing so, it is possible to accurately detect the ejection failure of the nozzle without being affected by the arrangement shape of the material ejected in the preliminary-ejecting area and regardless of the detecting time.

Furthermore, in the material arranging method, it is preferable that the detection step be performed at the time of changing the material in the ejection step.

By doing so, it is possible to detect in advance the ejection failure of the nozzle due to the change of material before ejecting the material in the predetermined area.

Furthermore, the material arranging method according to the present invention is a material arranging method of arranging a material on a base, the method comprising: an ejection step of ejecting the material from at least one nozzle toward a predetermined area of the base, which is provided in a vacuum atmosphere that is adjusted to a high degree of vacuum; and a preliminary ejection step of preliminarily ejecting the material from the nozzle toward an area on the base other than the predetermined area, before starting the ejection step.

According to the aforementioned method, by ejecting the material from at least one nozzle toward a predetermined area of the base, which is provided in a vacuum atmosphere that is adjusted to a high degree of vacuum, movement of the material is promoted by use of the pressure difference between the inside of the nozzle and the atmospheres in which the base is provided, and it is thus possible to arrange the material on the base. Furthermore, by making the place in which the base is provided to the vacuum atmosphere, a material which is in a solid state under the atmospheric pressure can be converted into a liquid or gas state in arrangement on the base, and as a result, the movement of material can be facilitated. For this reason, in the material arranging method, the degree of freedom in selection of material is increased, and for example, a material having a low solubility can be arranged on a substrate without dissolving the material in a solvent.

Furthermore, it is possible to arrange various materials such as high-molecular materials or low-molecular materials on the base, and also, by avoiding use of solvent or decreasing use amount of solvent, it is possible to avoid disadvantages such as deterioration of materials due to residual of solvent. Furthermore, by controlling the pressure of vacuum atmosphere, it is possible to discharge materials at molecular level from the nozzles, and as a result, it is possible to form a material film having much higher purity or control thickness of the material film with a high accuracy. Furthermore, by discharging the materials at a molecular level, it is facilitated to concurrently discharge a plurality of materials and mix them, and thus it is possible to form a functional film having a specific function on the base.

Furthermore, in the material arranging method, since the material is preliminarily ejected from the nozzle toward an area on the base other than the predetermined area before starting the ejection step, it is possible to always stabilize the amount of ejection of the material into the predetermined area. That is, for example, in a state of continuously ejecting the material, the ejection amount of material from each nozzle is stabilized, but the ejection amount of material when the ejection is re-started after an action such as resting the ejection of material may not be stabilized due to influences such as sticking of material in the nozzle. However, such non-stabilization does not occur by means of the preliminary ejection.

Furthermore, in the material arranging method, it is preferable that the vacuum atmosphere be adjusted to a pressure of 10⁻³ torr (1.33322×10⁻¹ Pa) or less, and it is more preferable that the vacuum atmosphere be adjusted to a pressure of 10⁻⁵ torr (1.33322×10⁻³ Pa) or less.

By adjusting the vacuum atmosphere to 10⁻³ torr or less, a material whose ejection from the nozzle is difficult under the atmospheric pressure can be easily ejected from the nozzle, and by adjusting the vacuum atmosphere to 10⁻⁵ torr or less, it is possible to eject more kinds of materials and also to gasify the material to be ejected for facilitating the ejection.

Furthermore, in the material arranging method, the preliminary ejection step performs the preliminary ejection of the nozzle in a process immediately previous to the ejection step.

By doing so, since the main ejection can be performed right after the preliminary ejection, it is possible to arrange the material while maintaining the ejection stability of the nozzle at high level after the preliminary ejection.

Furthermore, in the material arranging method, the preliminary ejection step is performed at the time of changing the material in the ejection step.

By doing so, the non-stability in the ejection amount of material due to change of material can be previously solved before the ejection of material.

Furthermore, the material arranging method may further comprises a positional correction step of detecting an arranged position of the material arranged through the preliminary ejection and a target position to arrange the material through the preliminary ejection right after the preliminary ejection step, and performing a positional correction of the nozzle when a positional deviation occurs between the arranged position and the target position.

According to the aforementioned method, by detecting an arranged position of the material arranged through the preliminary ejection and a target position to arrange the material through the preliminary ejection right after the preliminary ejection step, and performing a positional correction of the nozzle when a positional deviation occurs between the arranged position and the target position, even when the positional deviation occurs, it is possible to perform the positional correction without increasing the process time for the material arranging process, and thus the stable arrangement of material can be performed.

In a method of manufacturing an electronic device according to the present invention, at least some elements constituting the electronic device are formed using the material arranging method described above.

Since the method of manufacturing the electronic device uses the aforementioned material arranging method, the degree of freedom in selection of material is high and thus the optimization of structure can be easily accomplished. Moreover, since there is no disadvantage due to residual of solvent, a long life span of an electronic device can be accomplished. Furthermore, by forming a material film having a higher purity or a specific functional film, it is possible to manufacture a transistor or a memory element having a high quality or a high functionality. Furthermore, by stabilizing the ejection of material, it is possible to manufacture an electronic device at a low cost.

Furthermore, in the method of manufacturing the electronic device, a material for forming at least one of a conductive layer, a semiconductor layer, and an insulating layer constituting a transistor or a memory element is arranged as the material, and then the conductive layer, the semiconductor layer, or the insulating layer is formed.

According to this manufacturing method, since the materials for forming the conductive layer, the semiconductor layer and the insulating layer can be selected with a high degree of freedom, and the conductive layer, the semiconductor layer, or the insulating layer can be formed without using solvent, the life span of the element obtained can be enhanced.

Furthermore, in the method of manufacturing the electronic device, patterns for separating wires from each other are formed in advance on the base, the forming material is arranged in the patterns and then the conductive layer is formed.

According to this manufacturing method, even when the forming material is ejected and the landing position thereof is a little deviation, if the material is landed in the patterns, it is possible to form the conductive layer at desired positions, and as a result, by forming wires comprising the conductive layer or the like at the desired positions, respectively, it is possible to enhance circuit characteristics.

In a method of manufacturing an electro-optical device according to the present invention, at least some elements constituting the electro-optical device are formed using the material arranging method described above.

In the method of manufacturing the electro-optical device, since the aforementioned material arranging method is used, the degree of freedom in selection of material is high and thus the optimization of structure can be easily accomplished. Moreover, since there is no disadvantage due to residual of solvent, a long life span of an electro-optical device can be accomplished. Furthermore, by forming a material film having a higher purity or a specific functional film, it is possible to manufacture an electro-optical element having a high quality or a high functionality. Furthermore, by stabilizing the ejection of material, it is possible to manufacture an electro-optical device at a low cost.

Furthermore, in the method of manufacturing the electro-optical device, a material for forming at least one of an electron-transporting layer, a hole-transporting layer, a light-emitting layer, and electrodes constituting an organic electroluminescent element is arranged as the material, and then the electron-transporting layer, the hole-transporting layer, the light-emitting layer, or the electrodes is formed.

According to this manufacturing method, since the material for forming the electron-transporting layer, the hole-transporting layer, the light-emitting layer or the electrodes can be selected with a high degree of freedom, and since the electron-transporting layer, the hole-transporting layer, the light-emitting layer or the electrodes can be formed without using solvent, the life span of the element obtained can be enhanced.

Furthermore, in the method of manufacturing the electro-optical device, partitions for separating pixels from each other are formed in advance on the base, the forming material is arranged in the partitions, and then the electron-transporting layer, the hole-transporting layer or the light-emitting layer are formed.

According to this manufacturing method, even when the forming material is ejected and the landing position thereof is a little deviation, if the material is landed in the partitions, it is possible to form the light-emitting layer, etc. at desired positions, and as a result, by forming pixels comprising the light-emitting layer or the like at the desired positions, respectively, it is possible to enhance display quality.

A film-forming apparatus according to the present invention comprises: a processing chamber; a pressure control system for controlling the pressure in the processing chamber to a low pressure; at least one nozzle provided in the processing chamber and connected to a material supply source, for arranging a material on a member provided in the processing chamber; a stage provided in the processing chamber for holding the member; moving means for relatively moving the position of the nozzle or the stage; and inspecting means for inspecting the material arranged on the member.

According to the aforementioned film-forming apparatus, since the nozzles for ejecting the material and the pressure control system for controlling the pressure in the processing chamber are provided, it is possible to performing the aforementioned material arranging method according to the present invention. That is, in this film-forming apparatus, by controlling the pressure of the inside of the processing chamber in which the base is provided to an atmosphere of the high degree of vacuum and ejecting the material from the nozzles toward the base in the processing chamber the pressure of which is controlled, the movement of the material supplied into the processing chamber is promoted by means of the pressure difference to arrange the material on the base, and thus it is possible to form the material film on the base. Furthermore, by lowering the pressure of the inside of the processing chamber to a vacuum pressure, a material which is in a solid state under the atmospheric pressure can be converted into a liquid or gas state in the processing chamber, and as a result, the movement of material can be facilitated. For this reason, in this film-forming apparatus, the degree of freedom in selection of material is high, and it is possible to arrange various materials such as high-molecular materials or low-molecular materials on the base.

Furthermore, by avoiding use of solvent or decreasing use amount of solvent, it is possible to avoid disadvantages such as deterioration of material film due to residual of solvent. Furthermore, in this film-forming apparatus, by controlling the pressure of the inside of the processing chamber, it is possible to discharge the materials at molecular level from the nozzles, and as a result, it is possible to form a material film having much higher purity or control thickness of the material film with a high accuracy. Furthermore, by discharging the materials at a molecular level, it is facilitated to concurrently discharge a plurality of materials and mix them, and thus it is possible to form a functional film having a specific function on the base.

Furthermore, by inspecting the ejected material, it is possible to rapidly detect the abnormality, decrease of defectives can be accomplished, and also it is possible to always stabilize the ejection condition of the material. That is, before arranging the material in the patterning area on the base, by inspecting the abnormality such as the ejection failure of the nozzles, it is possible to prevent a plurality of defectives from being manufactured and thus to enhance the production yield of products.

Furthermore, although at least one nozzle is provided, even when a head comprising a plurality of nozzles is provided, the same operations and effects as the film-forming apparatus described above is obtained.

Furthermore, in the film-forming apparatus, the member may be a base having a predetermined area in which a film of the material is formed, and may be a preliminary member having a preliminary-ejecting area.

According to this device, since the main ejection can be performed right after the inspection, it is possible to arrange the material in a state in which the ejection stability of the nozzles after the preliminary ejection is maintained at a high level.

Furthermore, in the film-forming apparatus, it is preferable that the nozzles further comprise a preliminary nozzle to be used in place of the nozzle having an ejection failure, when the ejection failure occurs in one of the nozzles.

By doing so, when the ejection failure occurs in one of the nozzles, since the preliminary nozzle can be used in place of the nozzle having the ejection failure, it is not necessary to exchange the nozzles every time when the ejection failure occurs, and thus it is possible to shorten the process time.

Furthermore, in the film-forming apparatus, the inspecting means comprises detecting means for detecting an ejection failure of the nozzles on the basis of an ejecting result of the material.

According to this film-forming apparatus, since the ejection failure of the nozzles can be detected in the vacuum atmosphere, it is possible to rapidly detect the ejection failure of the nozzle, and as a result, it is possible to accomplish decrease of defectives and also to always stabilize the ejection condition of the material.

Furthermore, in the film-forming apparatus, the inspecting means further comprises position correcting means for detecting an arranged position of the material and a target position to arrange the material and performing a positional correction of the nozzles when a positional deviation occurs between the arranged position and the target position.

According to this film-forming apparatus, by detecting an arranged position of the material arranged through the preliminary ejection and a target position to arrange the material through the preliminary ejection, and performing a positional correction of the nozzle when a positional deviation occurs between the arranged position and the target position, even when the positional deviation occurs, it is possible to perform the positional correction without increasing the process time for the material arranging process, and thus the stable arrangement of material can be performed.

An electronic device or an electro-optical device according to the present invention is manufactured using the film-forming apparatus.

Since the electronic device or the electro-optical device is manufactured using the aforementioned film-forming apparatus, the degree of freedom in selection of material is high and thus the optimization of structure can be accomplished. For this reason, a long life span, a high quality or a high functionality can be accomplished. Furthermore, it is possible to prevent a plurality of defectives from being manufactured and it is thus possible to enhance the production yield of products.

An electronic apparatus according to the present invention comprises the electro-optical device as a display means.

According to this electronic apparatus, a long life span, a high quality or a high functionality of the display means can be accomplished, and it is also possible to accomplish a low cost due to enhancement of the production yield.

### BRIEF DESCRIPTION OF THE DRAWINGS

FIG. 1 is a view schematically illustrating an example of a film-forming apparatus according to a first embodiment of the present invention.

FIG. 2 is a view illustrating a state in which a material for forming a light-emitting layer constituting an organic EL element is arranged on a base.

FIG. 3 is a view conceptually illustrating an example of a material arranging method of the present invention.

FIG. 4 is a view schematically illustrating a constructional example of a pressure control system.

FIG. 5 is a view schematically illustrating a constructional example of a material supply system.

FIG. 6 is a view schematically illustrating a connectional example of a plurality of nozzles and a material supply source.

FIG. 7 is a view schematically illustrating a constructional example of a discharge head in which a plurality of nozzles is provided.

FIG. 8 is a view illustrating a constructional example of a discharge mechanism.

FIG. 9 is a view schematically illustrating a constructional example of a main control system.

FIG. 10 is a view illustrating an example of a relative moving state of a base and the discharge head (nozzles) at the time of arranging the material.

FIG. 11 is a flowchart illustrating a film forming process by the film-forming apparatus according to the first embodiment of the present invention.

FIG. 12 is a view illustrating an example of patterns of a preliminary ejection.

FIG. 13 is a view illustrating an example of patterns of a preliminary ejection.

FIG. 14 is a view illustrating an example of patterns of a preliminary ejection.

FIG. 15 is a view illustrating a state in which the ejection condition is unstable in the initial time of ejecting the material.

FIG. 16 is a view illustrating a state in which the length of the preliminary-ejecting area is varied due to variation of the ejection condition in the initial time of ejecting the material.

FIG. 17 is a view illustrating an example of patterns of the preliminary ejection.

FIG. 18 is a view illustrating an example of patterns of the preliminary ejection.

FIG. 19 is a view schematically illustrating an example of a film-forming apparatus according to a fourth embodiment of the present invention.

FIG. 20 is a block diagram of the film-forming apparatus according to the fourth embodiment of the present invention.

FIG. 21 is a view illustrating in detail arrangements of the discharge head, the sensor and the light source shown in FIG. 19.

FIG. 22 is a flowchart illustrating operations of the film-forming apparatus according to the fourth embodiment of the present invention.

FIG. 23 is a view illustrating an example of a circuit of an active matrix type organic EL display device according to a fifth embodiment of the present invention.

FIG. 24 is a plan view illustrating an example of a planar structure of a pixel unit in the display device shown in FIG. 23.

FIG. 25 schematically illustrates a cross-sectional structure of the pixel unit (organic EL element), where (a) shows a top emission type and (b) shows a back emission type.

FIG. 26 is a view illustrating an enlarged cross-sectional structure of the pixel unit (organic EL element) of the top emission type.

FIG. 27 is a view illustrating an embodiment in which the method of manufacturing an electro-optical device of the present invention applies to a process of manufacturing a display device comprising the organic EL elements.

FIG. 28 is a view illustrating an embodiment in which the method of manufacturing an electro-optical device of the present invention applies to a process of manufacturing a display device comprising the organic EL elements.

FIG. 29 is a view illustrating an embodiment in which the method of manufacturing an electro-optical device of the present invention applies to a process of manufacturing a display device comprising the organic EL elements.

FIG. 30 is a view illustrating an embodiment in which the method of manufacturing an electro-optical device of the present invention applies to a process of manufacturing a display device comprising the organic EL elements.

FIG. 31 is a view illustrating another example of the organic EL element.

FIG. 32 is a view illustrating another example of the organic EL element.

FIG. 33 is a view illustrating another example of a circuit of the organic EL display device.

FIG. 34 is a view illustrating an example of an electronic apparatus according to a sixth embodiment of the present invention.

FIG. 35 is a view illustrating another example of an electronic apparatus according to the sixth embodiment of the present invention.

FIG. 36 is a view illustrating another example of an electronic apparatus according to the sixth embodiment of the present invention.

FIG. 37 is a view illustrating another example of an electronic apparatus according to the sixth embodiment of the present invention.

FIG. 38 is a view illustrating another example of an electronic apparatus according to the sixth embodiment of the present invention.

FIG. 39 is a view illustrating another example of an electronic apparatus according to the sixth embodiment of the present invention.

### DETAILED DESCRIPTION OF PREFERRED EMBODIMENTS

Now, a material arranging method, a film-forming apparatus, an electro-optical device and a manufacturing method thereof, an electronic device, and an electronic apparatus according to embodiments of the present invention will be described in detail.

[First Embodiment]

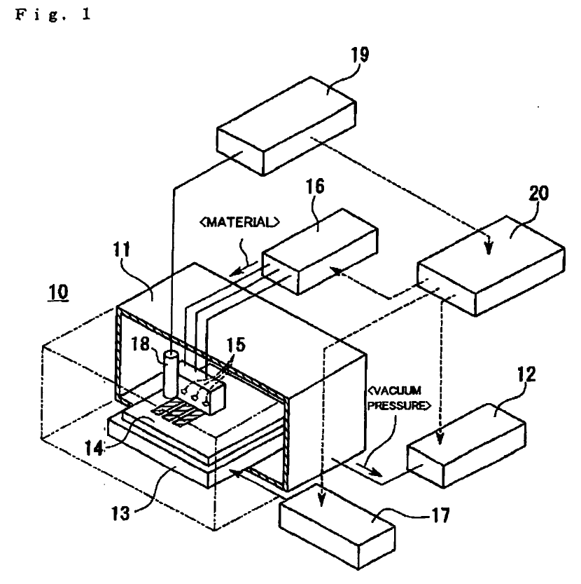

FIG. 1 is a perspective view schematically illustrating an example of a film-forming apparatus according to a first embodiment of the present invention.

The film-forming apparatus is used for processes of manufacturing an electro-optical device comprising EL elements, liquid crystal display elements, image pickup elements (CCD), electron discharge elements, electrophoresis elements or the like used as displays or display light sources, or an electronic device such as a semiconductor element, a magnetic head, a color filter, a touch panel or the like, and arranges materials on a base to form the material films in order to form a part of elements constituting these devices.

The film-forming apparatus 10 comprises a vacuum chamber 11 which is a processing chamber, a pressure control system 12 for controlling the inside of the vacuum chamber 11 to a predetermined vacuum pressure, a base stage 13 provided in the vacuum chamber 11, a base 14 which is set to the base stage 13, nozzles 15 for ejecting material on the base 14, a material supply system 16 for supplying the material to the nozzles 15, a driving system 17 for relatively positioning the base 14 and the nozzles 15, a television camera 18 into which sensors are assembled for detecting non-ejection of the material from the nozzles 15, a detecting system 19 having an image processing device (not shown) for processing data fetched from the television camera 18 and inspecting the non-ejection of the material, and a main control system 20 for totally controlling these mechanisms.

As the base 14, various well-known bases used in electro-optical devices or electronic devices, such as a glass substrate, a silicon substrate, a quartz substrate, a ceramics substrate, a metal substrate, a plastic substrate, a plastic film substrate or the like, are used. Further, as materials arranged on the base 14, various materials used in electro-optical devices or electronic devices, such as optical materials, materials for forming circuits or the like, are used. Specifically, since the film-forming apparatus of the present invention has a high degree of freedom in selection of materials as described later, a large range of various materials such as high-molecular materials or low-molecular materials can be used.

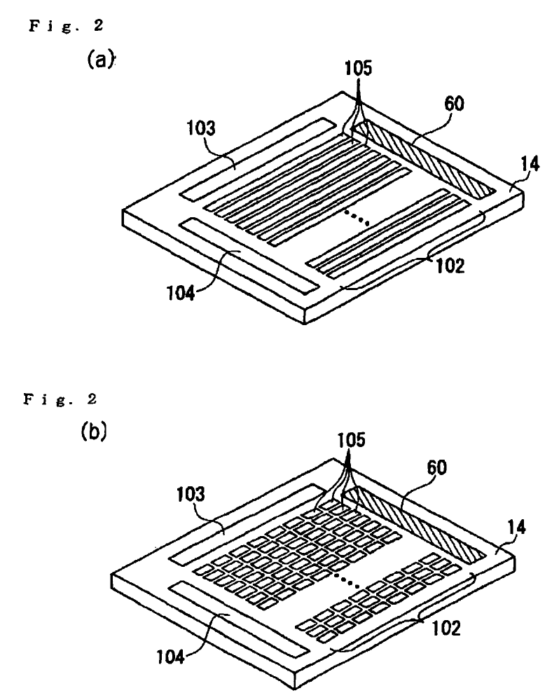

FIGS. 2(a) and 2(b) show a state in which as a material for forming a film, a material for forming a light-emitting layer constituting an organic EL element is arranged on the base 14.

In FIG. 2(a), pixel units 102, a data side driving circuit 103, a scanning side driving circuit 104, and a non-ejection detecting pattern area (preliminary-ejecting area) 60 are provided respectively on the base 14. In the pixel unit 102, the material for forming a light-emitting layer is arranged in a stripe shape on the base 14, and as a result, the light-emitting layer (EL layer) 105 is formed in a stripe-shaped array on the base 14.

Furthermore, in FIG. 2(b), in the pixel unit 102, the material for forming a light-emitting layer is arranged in a matrix shape on the base 14, and as a result, a light-emitting layer 105 is formed in a matrix-shaped array on the base 14. In the EL element, in a case of performing a color display, the light-emitting layers corresponding to the respective colors of red, green and blue are formed in a predetermined array on the base 14. The film-forming apparatus 10 shown in FIG. 1 arranges a predetermined material on the base 14 in order to form these light-emitting layers on the base 14. Furthermore, in FIG. 2, the driving circuits 103, 104 are mounted on the base 14, but they may be mounted externally (on an IC chip, etc. provided externally). A detailed constructional example of the organic EL element will be described later as one example of the electro-optical device of the present invention.

FIG. 3 is a view conceptually illustrating an example of a material arranging method of the present invention, in which a material is arranged on the base 14 using the film-forming apparatus 10. In the film-forming apparatus 10 of this example, the inside of the vacuum chamber 11 in which the base 14 is arranged is controlled to a pressure (a vacuum pressure) lower than the inside of the nozzle 15 by means of the pressure control system 12, and the material is discharged from the nozzles 15 toward the base 14 in the vacuum chamber 11 the pressure of which is controlled.

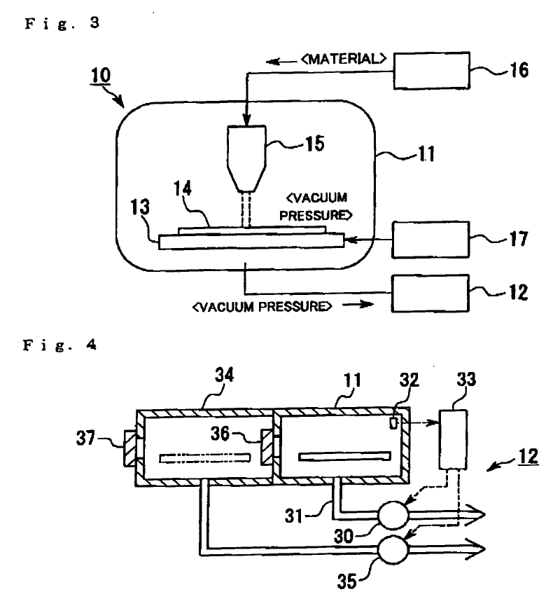

FIG. 4 schematically illustrates a constructional example of the pressure control system 12. The pressure control system 12 comprises a vacuum unit 30 for exhausting the inside of the vacuum chamber 11 to lower the pressure in the vacuum chamber 11, an exhaustive piping 31 connected to the vacuum chamber 11, a manometer 32 for measuring the vacuum pressure of the inside of the vacuum chamber 11, and a control mechanism 33 for controlling the vacuum unit 30 on the basis of the measured result of the manometer 32. As the vacuum unit 30, for example, a high vacuum pump such as a turbo molecular pump, a cryopump, an ion pump, a sublimation pump or the like, a low vacuum pump such as a rotary pump or a dry pump, and combinations of the high vacuum pump and the low vacuum pump are used. Furthermore, the vacuum chamber 11 is constructed to be gas-tight and also is designed to have a pressure-proof structure capable of withstanding the set vacuum pressure.

Furthermore, it is preferable that the pressure control system 12 be provided with a vibration-proof mechanism or a vibration-removing mechanism such that the vibrations at the time of operation of the vacuum unit 30 are not propagated into the vacuum chamber 11. Furthermore, it is preferable that a preliminary chamber 34 be provided adjacently to the vacuum chamber 11 so that the degree of vacuum of the inside of the vacuum chamber 11 is not lowered when the base 14 is carried in and carried out. In this case, the preliminary chamber 34 comprises a vacuum unit 35 for lowering the internal pressure to the degree of vacuum equal to the degree of vacuum of the inside of the vacuum chamber 11 and opening and closing mechanisms 36, 37 for opening and closing an opening for carrying-in or carrying-out the base 14. Furthermore, a carrying mechanism for carrying the base 14 may be provided in the preliminary chamber 34, and may be provided externally.

When the base 14 is carried in the vacuum chamber 11, the base 14 is first arranged in the preliminary chamber 34, the pressure in the preliminary chamber 34 is controlled to a pressure equal to the pressure in the vacuum chamber 11, the opening and closing mechanism 36 between the preliminary chamber 34 and the vacuum chamber 11 is opened, and then the base 14 is carried in the vacuum chamber 11. On the contrary, when the base 14 is carried out from the vacuum chamber 11, the pressure in the preliminary chamber 34 is controlled to a pressure equal to the pressure in the vacuum chamber 11, the opening and closing mechanism 36 is opened, the base 14 is carried in the preliminary chamber 34, the opening and closing mechanism 36 is closed, and then the base 14 is carried out from the preliminary chamber 34 to the outside. As a result, the degree of vacuum of the vacuum chamber 11 can be maintained stably.

As shown in FIG. 3, the inside of the vacuum chamber 11 is controlled to a pressure lower than the inside of the nozzle 15 by the pressure control system 12, and the material is discharged from the nozzles 15 toward the base 14 in the vacuum chamber 11 the pressure of which is controlled. Therefore, by means of the pressure difference between the inside of the nozzle 15 and the vacuum chamber 11, movement of the material discharged from the nozzles 15 is promoted, and thus the material discharged from the nozzles 15 is stably arranged on the base 14. Furthermore, by lowering the pressure in the vacuum chamber 11 to the vacuum pressure, the solid or liquid material under the atmospheric pressure can be converted into a liquid or gas state in the vacuum chamber 11, and thus the movement of the material can be facilitated. That is, in this embodiment, for a material which is difficult to move into the base 14 at a room temperature and under the atmospheric pressure, by changing the state (preferably, the phase) of the material in the vacuum pressure, the movement can be facilitated. Therefore, various materials can be arranged on the base 14.

For example, by controlling the inside of the vacuum chamber 11 to a high degree of vacuum, the material supplied from the nozzles 15 can be gasified to be discharged. As a result, a material having a low solubility can be arranged on the base 14 without dissolving the material in a solvent. That is, even when the material supplied from the nozzles 15 is a solid or a liquid having a high viscosity, by largely lowering the pressure in the vacuum chamber 11 to vaporize or sublimate the material, it is possible to move the material in a gas phase or a vapor phase from the nozzles 15 to the base 14.

It is preferable that the pressure in the vacuum chamber 11 be properly set in accordance with the characteristic of the used material such as a vapor pressure, and the pressure is controlled by the pressure control system 12 to a high degree of vacuum of 10⁻³ torr (1.33322×10⁻¹ Pa) or less or a high degree of vacuum of 10⁻⁵ torr (1.33322×10⁻³ Pa) or less. By controlling the inside of the vacuum chamber 11 to the high degree of vacuum of 10⁻³ torr or less, a material which is difficult to discharge from the nozzles 15 under the atmospheric pressure can be also easily discharged from the nozzles 15, and by controlling the inside of the vacuum chamber 11 to the high degree of vacuum of 10⁻⁵ torr or less, a large range of various materials can be discharged from the nozzles 15. Furthermore, by controlling the inside of the vacuum chamber 11 to the aforementioned high degree of vacuum, the sublimation or the vaporization of the material to be discharged from the nozzles 15 can be facilitated.

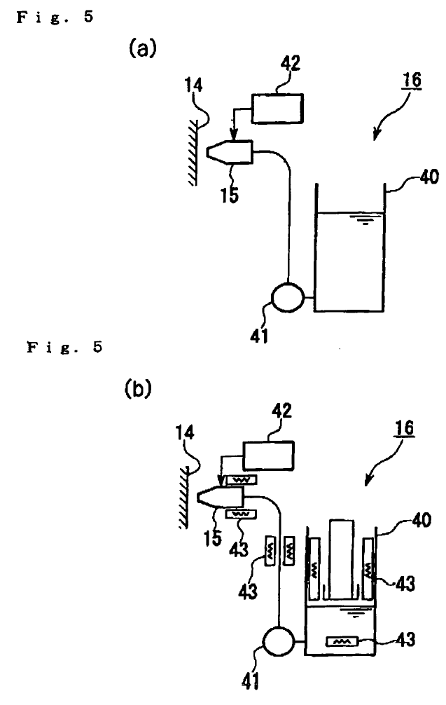

FIG. 5 is a conceptual view illustrating a constructional example of the material supply system 16. In the example of FIG. 5(a), the material supply system 16 is constructed to supply the material in a liquid state to the nozzles 15. That is, the material supply system 16 comprises a material supply source 40 including a tank for accommodating the liquid material, the a nozzle 15, a transporting means 41 such as a pump for transporting the material from the material supply source 40 to the nozzle 15, and a discharge mechanism 42 for controlling the discharge timing of the material from the nozzle 15. Furthermore, by using a capillary phenomenon or the gravity or a pressure difference, the transporting means 41 maybe omitted.

Furthermore, when a solid material is used at the room temperature and under the atmospheric pressure, as shown in FIG. 5(b), by heating and melting the material by means of a heating means 43 such as a heater, the material can be supplied to the nozzle 15 in a liquid state. In this case, the heating means 43 is preferably provided, for example, in a piping on the transporting path or in the nozzle 15 other than the tank in which the material is accommodated.

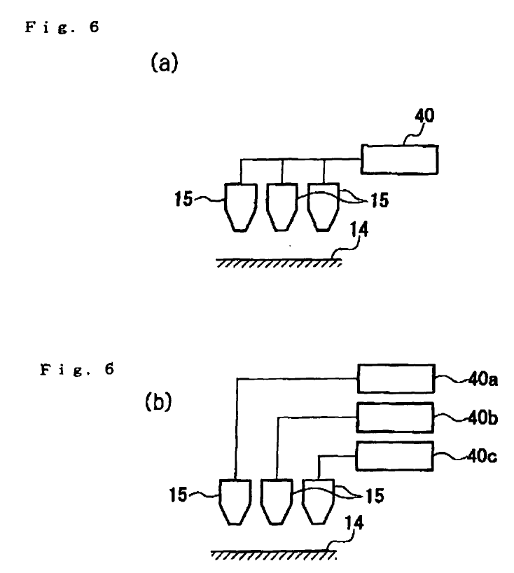

At least one nozzle 15 is provided in the vacuum chamber 11, but in this embodiment, a plurality of nozzles is provided and each of them is connected to the material supply source 40. FIG. 6 schematically illustrates a connection example of the plurality of nozzles 15 and the material supply source 40, where FIG. 6(a) illustrates an example in which the plurality of nozzles 15 is connected to the same material supply source 40 and FIG. 6(b) illustrates an example in which the plurality of nozzles 15 are connected to the material supply sources 40a, 40b, 40c which are different from one another. The plurality of nozzles 15 are connected to the same material supply source 40, and by discharging the same material from the plurality of nozzles 15 toward the base 14, the area in which the material can be arranged at a time is enlarged or the amount of supply of material per an hour can be increased, so that it is possible to increase the throughput. Furthermore, the plurality of nozzles 15 are connected to the material supply sources 40a, 40b, 40c which are different from each other, and by discharging different materials from the plurality of nozzles 15 toward the base 14, films made of a plurality of different materials can be formed on the base 14. For example, when the light-emitting layer of the EL element described using FIG. 2 is formed on the base, by discharging the material for forming the light-emitting layers corresponding to the respective colors of red, green and blue from the different nozzles, respectively, the light-emitting layers corresponding to the respective colors can be formed in a predetermined array pattern on the base.

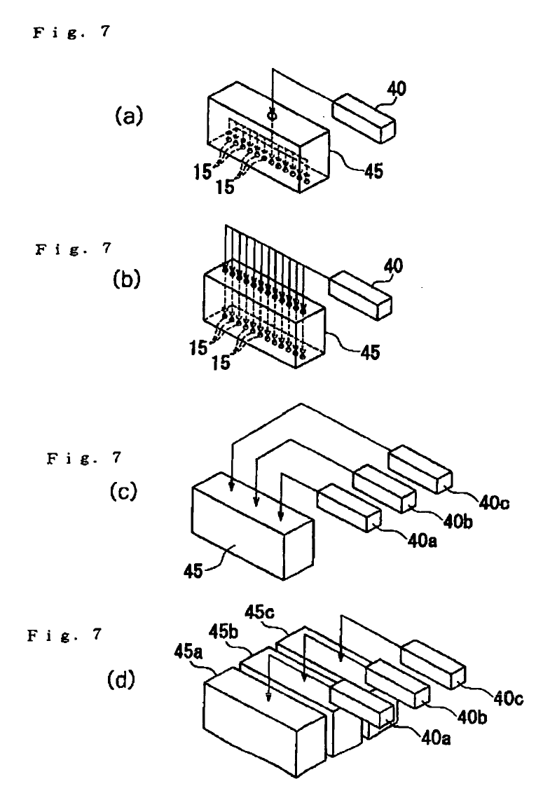

Furthermore, in this embodiment, the plurality of nozzles 15 is incorporated into the same object. FIGS. 7(a) to 7(d) schematically illustrate constructional examples of a discharge head 45 as the object in which the plurality of nozzles 15 are provided. In FIG. 7(a), the discharge head 45 is connected to one material supply source 40, and the material supplied from the material supply source 40 is branched within the discharge head 45 and is carried to the respective nozzles 15.

Furthermore, in FIG. 7(b), the discharge head 45 is connected to one material supply source 40, and the material supplied from the material supply source 40 is branched before entering the discharge head 45, is not branched within the discharge head 45 and is carried to the respective nozzles 15 in the state as it is. In this case, non-uniformity in energy loss due to branching within the nozzles is removed, and thus it is possible to supply more uniformly the material.

Furthermore, in FIG. 7(c), the discharge head 45 is connected to the plurality of material supply sources 40a, 40b and 40c different from each other, and the materials supplied from the respective material supply sources 40a, 40b and 40c are carried to predetermined nozzles previously matched out of the plurality of nozzles provided in the discharge head 45.

Furthermore, in FIG. 7(d), the discharge head comprises a plurality of discharge heads 45a, 45b and 45c, and each of them is connected to the different material supply sources 40a, 40b and 40c, respectively. A construction of these discharge head 45 or the supply path of the materials is properly determined in accordance with the materials to be used. Furthermore, in the plurality of nozzles 15 provided in the discharge heads, the timings of discharging the materials are controlled individually by the discharge mechanism 42 (see FIG. 5).

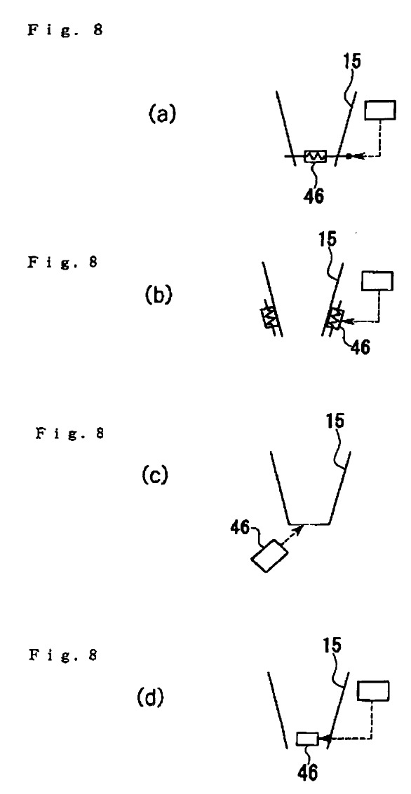

As the discharge mechanism 42, for example, a mechanical shutter system for mechanically controlling the timing of discharging the materials by means of the opening and closing of a shutter can be employed. FIG. 8 illustrates constructional examples of the discharge mechanism 42, and the discharge mechanism 42 of this embodiment gasifies (vaporizes) the material to discharge it from the nozzle 15, by heating the liquid-state material in the nozzle 15.

In FIG. 8, the discharge mechanism 42 has a heating means 46 for heating the material in the nozzle 15, and is constructed to control the timing of discharging the material by controlling the heating timing. The heating means 46 for discharging material can includes, for example, an electrical heater (FIGS. 8(a) and 8(b)), a laser such as YAG laser (FIG. 8(c)) or a high frequency heater (FIG. 8(d)), etc. Furthermore, the heating means 46 is not limited to these, and may use various heating means well known. Furthermore, when the material is gasified and discharged from the nozzles 15, it is preferable that the heating means 46 be provided to heat the vicinity of a surface of the material in the nozzle 15 facing the base 14. By doing so, the material can be gasified effectively from the surface of the material.

In this embodiment, since the pressure in the vacuum chamber 11 (see FIG. 3) provided with the base 14 is controlled to a pressure (a vacuum pressure) lower than the inside of the nozzle 15, the material can be easily gasified (vaporized) in the vacuum chamber 11 by heating the material discharged from the nozzle 15. Specifically, when the inside of the vacuum chamber 11 is controlled to a high degree of vacuum, the boiling point of the material is largely decreased and thus the material can be easily gasified (vaporized) with a relatively small heat capacity. The gasified material is discharged from the nozzle 15 in a gas or vapor state, is moved toward the base 14, is cooled and then liquefied or hardened through, for example, heat exchange with the base 14 after reaching the base 14 to be fixed on the base 14.

Then, a predetermined amount of material is arranged on the base 14, and thus a material film is formed on the base 14.

When the material is gasified and discharged from the nozzle 15 in the vacuum chamber 11 controlled to a high degree of vacuum, the material can be discharged at a molecular level (in a molecular beam) or at an atomic level (in an atomic beam). Then, by arranging the material discharged at a molecular level or at an atomic level on the base 14, a material film having a much higher purity can be formed on the base 14, or the thickness of the material film can be controlled with a high accuracy. That is, since the inside of the vacuum chamber 11 is controlled to a high degree of vacuum, it is difficult for impurities to be doped into the material supplied from the nozzle 15, and by discharging the material at a molecular level or at an atomic level and then arranging the material on the base 14, it is possible to control the film thickness at the molecular or atomic level. Specifically, since materials can be discharged from the plurality of nozzles 15 at the same time and the plurality of materials can easily be mixed, in this case, it is easy to form a functional film having a specific function on the base 14.

In the detecting system 19, the detection of ejection failure of the nozzles 15 can be performed through a spectroscopic means such as detecting light-reflectivity of the material ejected to the non-ejection detecting pattern area 60 or detecting light-transmissivity thereof. By doing so, it is possible to accurately detect the ejection failure of the nozzles without being affected by the arrangement shape of the material ejected to the non-ejection detecting pattern area 60 and regardless of the detecting time.

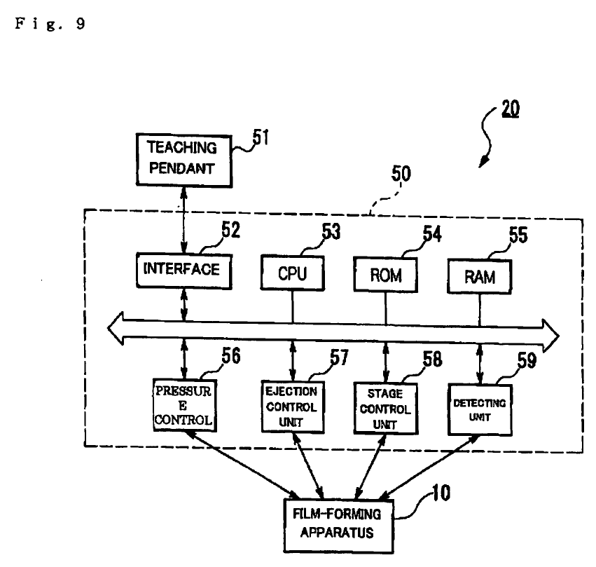

FIG. 9 is a conceptual view illustrating the main control system 20 of the film-forming apparatus 10. The main control system 20 comprises a managing controller 50 which is a main body including various control units and a teaching pendant 51 which is an input/output means of the managing controller 50.

The teaching pendant 51 comprises a display unit for displaying information such as progress situation of the material arrangement, existence of abnormal nozzles or the like, and a manipulating unit for indicating operations of the film-forming apparatus 10, but not shown.

The managing controller 50 comprises an interface 52 for performing delivery of data with the teaching pendant 51, a CPU 53 for controlling the film-forming apparatus 10, a ROM 54 for memorizing control programs for operating the CPU 53, a RAM 55 for memorizing an abnormality information, a pressure control unit 56 connected to the pressure control system 12 for controlling the pressure in the vacuum chamber 11, an ejection control unit 57 connected to the material supply system 16 for controlling the ejection of material, a stage control unit 58 connected to the driving system 17 for controlling operations of the base stage 13, and a detecting unit 59 connected to an image processing device included in the detecting system 19.

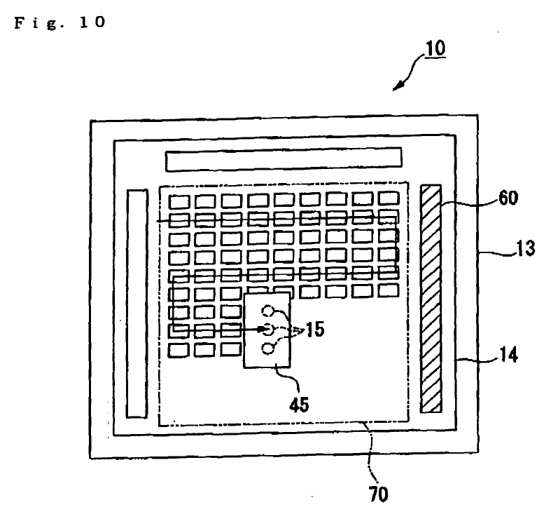

FIG. 10 is a view illustrating an example of a relatively moving state of the base 14 and the discharge head 45 (nozzles 15) at the time of arranging material (at the time of patterning). Furthermore, in FIG. 10, an XYZ orthogonal coordinates system is used, wherein in the XYZ orthogonal coordinates system, an X axis and an Y axis are established to be parallel to the base stage 13 on which the base 14 is mounted and a Z axis is established in a direction perpendicular to the base stage 13.

In FIG. 10, the driving system 17 of this embodiment is disposed on the base not shown, and has the base stage 13 arranged to be freely driven in a two-dimensional plane (the XY plane of FIG. 10). The base stage 13 comprises a driving unit including, for example, a linear motor, and a temperature adjusting unit for heating and cooling the base 14 on the base stage 13, and in response to instructions of the main control system 20, adjusts the base 14 to a predetermined temperature and also performs the positioning or movement to a predetermined position of the base 14. That is, in the film-forming apparatus 10, by relatively moving the base 14 and the discharge head 45 (nozzles 15) while discharging the material from the nozzles 15 at the time of arranging the material (at the time of patterning), the material film is formed in a predetermined array on the base 14. Furthermore, by adjusting the base 14 to a predetermined temperature, deposition or hardening of the material arranged on the base 14 is promoted. Furthermore, a gap (a distance in a Z direction) between the base 14 and the discharge head 45 (nozzles 15) is adjusted by means of a Z driving unit not shown. Furthermore, the driving system 17 may comprise a means for adjusting a slope of the discharge head 45 or the base 14 with respect to the XY plane or a means for adjusting a rotational angle in the XY plane.

Furthermore, although in this example, the relative movement of the base 14 and the discharge head 45 (nozzles 15) at the time of patterning is performed by moving the base 14 through the base stage 13, the present invention is not limited to this, but the relative movement may be performed by moving the discharge head 45 and may be performed by moving both of the base 14 and the discharge head 45. When both of the base 14 and the discharge head 45 are moved, the scanning movement may be performed through movement of one side (for example, the discharge head 45) and the shift movement may be performed through movement of the other side (for example, the base 14). Furthermore, the formation of the material film is not completed at one place by means of one scanning movement, but the formation of the material film may be completed by repeating the scanning movement at the same place in the plurality of times. By doing so, the material film can be formed, for example, while growing (vapor-growing) the material on the base. In this case, by repeating the scanning movement in accordance with the growth of the material film, decrease of the throughput can be suppressed.

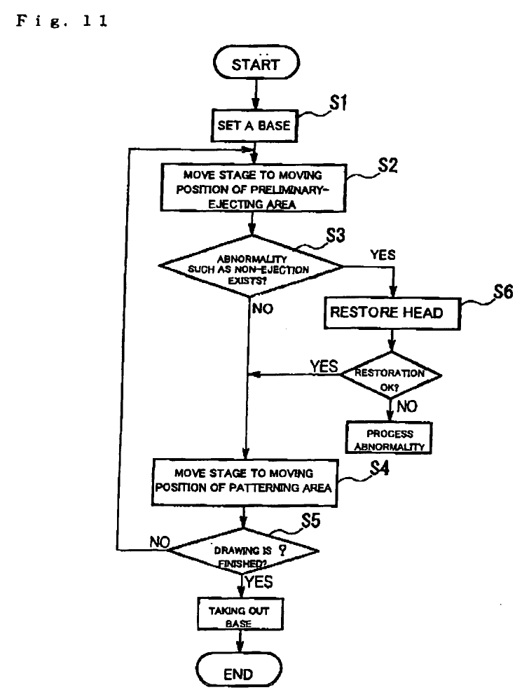

Next, the film forming process by use of the film-forming apparatus of this embodiment will be described in accordance with the flowchart shown in FIG. 11.

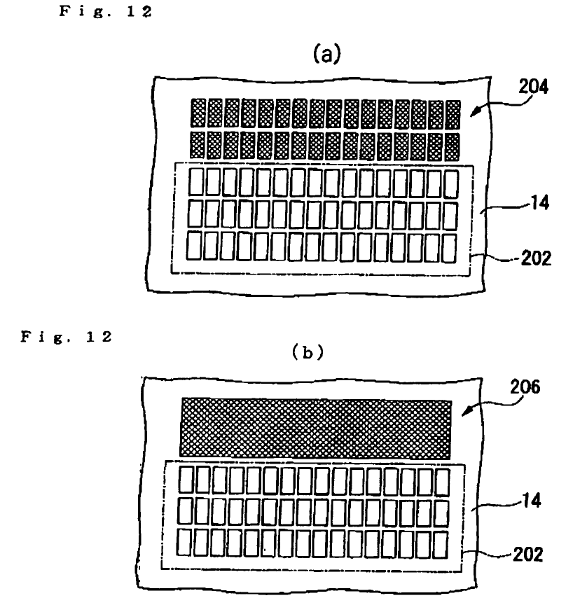

First, the base 14 is set on the base stage 13 in the film-forming apparatus 10 and the positioning thereof is performed (step S1). After performing the positioning, when the preliminary-ejecting area 60, which is disposed on the base 14, is moved right below the discharge head 45 (step S2), a drawing, for example, as shown in FIG. 12 is performed. The drawing pattern is recognized by the television camera 18 and the detecting system 19 (step S3), and when the abnormality dose not exist, the base stage 13 moves the patterning area 70 on the base 14 right below the discharge head 45 (step S4) and then the arrangement of material is performed. Furthermore, when a plurality of sheets of product substrates are obtained from a single base, for example, when a single base has two patterning areas, after the arrangement of material is finished, the base stage 13 is moved such that a second non-ejection detecting pattern area (not shown) on the base is positioned right below the discharge head 45 (step S5). Then, the same operation is repeated again and thus the arrangement of material is performed to the second patterning area (not shown).

On the other hand, when an abnormality such as non-ejection is detected in the step S3, the arrangement of material into the patterning area 70 is right stopped, and the restoring operation by means of a restoring means of the discharge head 45 is performed (step S6) or exchange of the discharge head 45 (step S7) is performed.

As described above, in the film-forming apparatus and the material arranging method of this example, since the degree of freedom in selection of materials is high, it is possible to arrange various materials such as high-molecular materials or low-molecular materials on the base. For this reason, by avoiding use of solvent or decreasing use amount of solvent, it is possible to avoid disadvantages such as deterioration of material films due to residual of solvent.

Furthermore, it is possible to discharge materials at molecular levels or atomic levels from the nozzles, and as a result, it is possible to form a material film having much higher purity or control thickness of the material film with a high accuracy. Furthermore, by concurrently discharging a plurality of materials and mixing them, it is possible to well form a functional film having a specific function on the base.

Furthermore, since it is possible to rapidly detect the ejection failure of the nozzles, decrease of defectives can be accomplished and it is possible to always stabilize the ejection condition of material. That is, before arranging the material in the patterning area on the base, by detecting the ejection failure of the nozzles, it is possible to prevent a plurality of defectives from being manufactured and thus to enhance the production yield of products.

[Second Embodiment]

Next, a second embodiment of the present invention will be described.

In the first embodiment, although the non-ejection detecting pattern is ejected on the base 14 from the discharge head 45 (nozzles 15) right before performing the arrangement of materials to the patterning area 70 of the base 14, in this embodiment, a preliminary ejection is performed on the base 14 to stabilize the ejecting condition of the discharge head 45 before performing the arrangement of materials to the patterning area 70.

FIG. 12 is a view illustrating patterns of the preliminary ejection on the base 14. As shown in FIG. 12, right before ejecting the material in a patterning area 202 on the base 14, the preliminary ejection is performed to preliminary-ejecting areas 204, 206 on the base 14, provided on one side of the patterning area 202. As the ejection pattern of material for the preliminary ejection, as shown in FIG. 12(a), the ejection may be performed at the same pitch as the array (line) pattern of the patterning area 202, and as shown in FIG. 12(b), the ejection may be performed to cover the whole surface of any range. Moreover, in addition to the preliminary ejection patterns as shown in FIGS. 12(a) and 12(b), for example, positioning alignment marks for bonding a counter substrate with a glass substrate as a base to construct a liquid crystal display device later may be formed by the preliminary ejection.

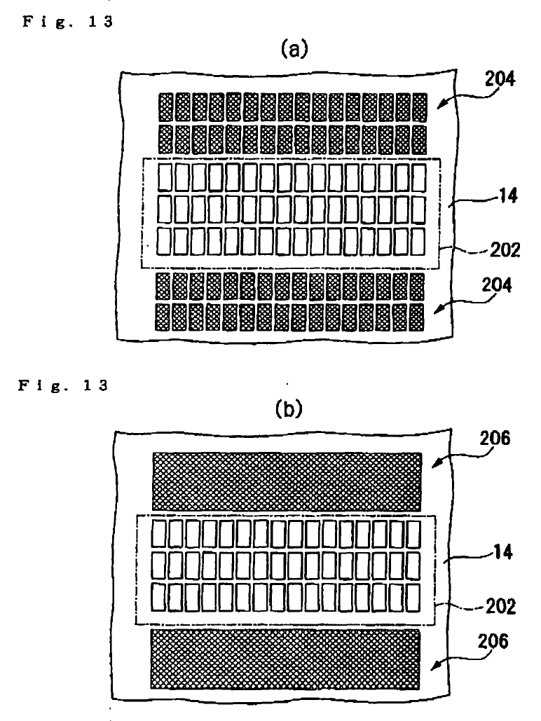

Furthermore, the shape of the preliminary-ejecting area is not limited to the shapes shown in FIGS. 12(a) and 12(b), but the preliminary-ejecting areas 204, 206 may be formed on both sides of the patterning area 202 as shown in FIGS. 13(a) and 13(b) and the preliminary-ejecting area may be formed to surround the patterning area as shown in FIGS. 14(a) and 14(b).

As described above, although the ejection amount of material from the respective nozzles is stable in a state in which the material is usually ejected continuously, once the ejection of material is stopped, the amount of material ejected when re-starting the ejection is not stable because the material is dried in the nozzles. However, according to this embodiment, the stable ejection of material can be always performed in the patterning area. Further, since the preliminary-ejecting area is close to the patterning area, the main ejection can be performed right after the preliminary ejection and thus the material can be arranged while maintaining the ejection stability of the nozzles after the preliminary ejection at a high level.

Furthermore, in the above embodiment, although an example in which the preliminary-ejecting area is provided on the base 14 is described, the present invention is not limited to this, but even if a reception portion (member) for preliminary ejection is provided in outside of the base and the preliminary ejection is performed on the reception portion, the similar effects can be obtained.

[Third Embodiment]

Next, a third embodiment of the present invention will be described.

In this embodiment, by starting the arrangement of material from the outer side of the patterning area to be substantially used, a film is formed in the patterning area by means of a uniform ejection amount of material.

In general, the discharge head 45 (nozzles 15) can eject the material stably while ejecting the material continuously or in a repeated pattern. However, when first starting the ejection or when being moved to a next line and performing the material arrangement, the initial ejection amount of material is not stabilized.

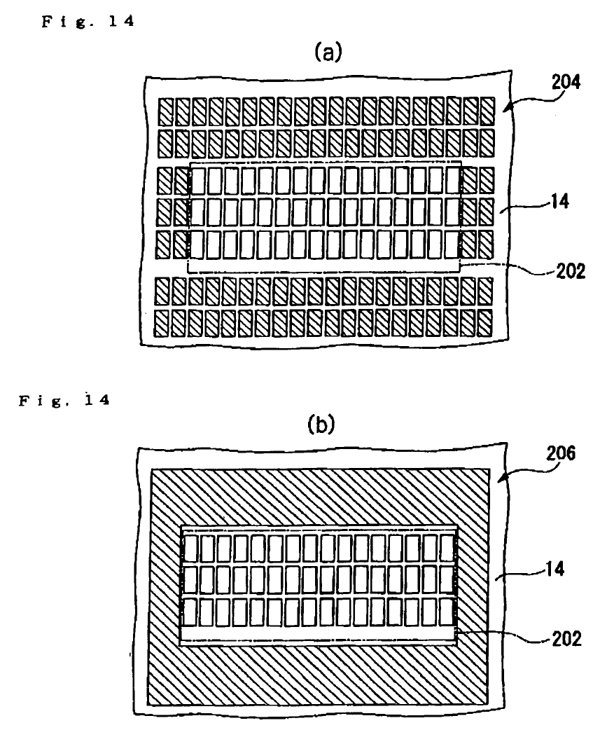

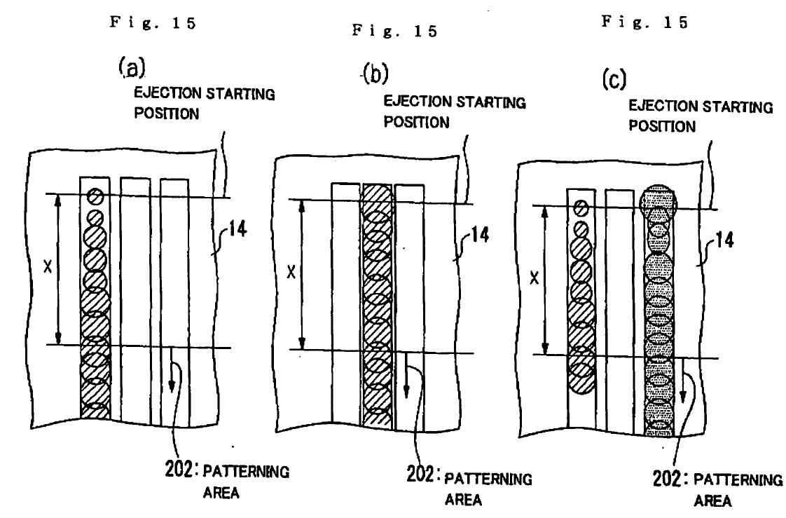

For example, as shown in FIG. 15(a), the first ejection amount of material may be smaller than a desired amount, as shown in FIG. 15(b), the first ejection amount of material may be lager than the desired amount, or as shown in FIG. 15(c), the landing point of material and the center of concentration of material may be deviated. These phenomena are generated because when the discharge head 45 or the base 14 is moved without ejecting the material, the concentration of material is varied or the viscosity of material is varied in the vicinity of the nozzles 15, for example, due to vaporization of material.

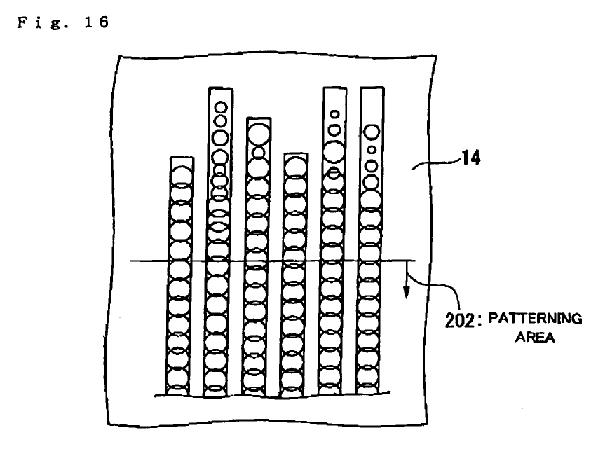

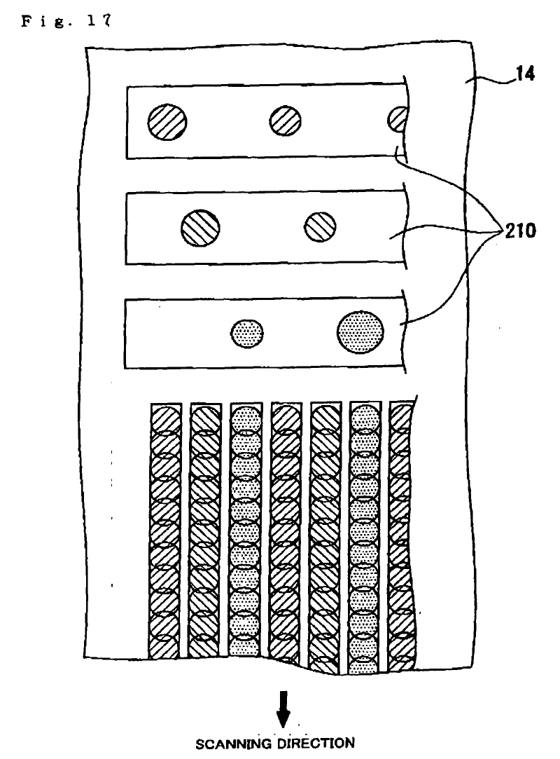

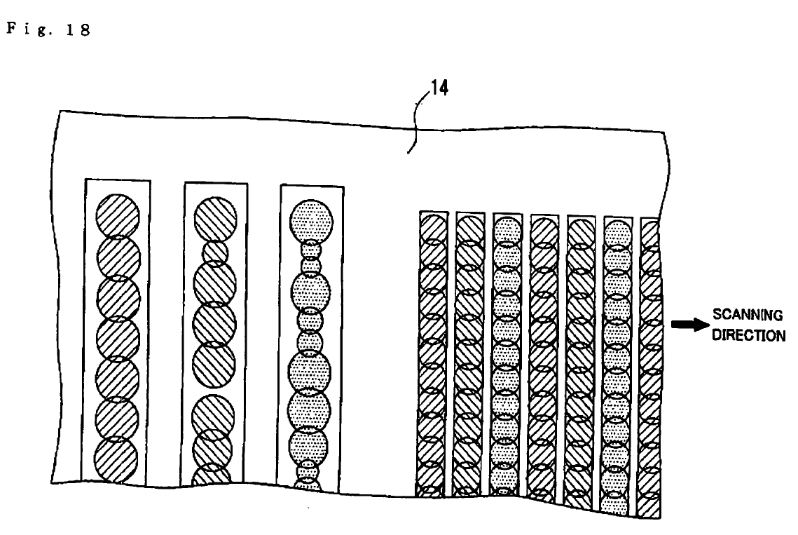

Furthermore, in the pattern of the preliminary ejection in this embodiment, a pattern similar to the patterning area 202 may extend as shown in FIG. 15, and the pattern may have a different shape. Furthermore, as shown in FIG. 16, only for the materials the ejection of which is not stable, the preliminary ejection across a long distance may be performed. Further, as shown in FIG. 17, a preliminary-ejecting area 210 may be provided at an end portion of the base 14, the material may be ejected until the ejection is stabilized in the preliminary-ejecting area 210, and then the arrangement of material may be started. Furthermore, as shown in FIG. 18, even when the scanning direction is perpendicular or oblique to the arranged pattern, there is no problem only if the preliminary-ejecting area is provided on a direction from which the scanning is started.

[Fourth Embodiment]

Next, a fourth embodiment of the present invention will be described.

FIG. 19 is a perspective view schematically illustrating a film-forming apparatus of this embodiment. The film-forming apparatus 300 comprises a moving mechanism 30 including a stage for moving the base 14 in the X and Y directions of FIG. 19, a rotational stage 302 for freely rotating the base 14 in a θ direction, a fixed board 303 for holding and fixing the base 14, a discharge head 304 having nozzles for ejecting materials, a sensor 305 for reading out patterns of the arranged material, a light source 306 for irradiating an image pickup range of the sensor 305, and alignment sensors 307, 308 for reading out the alignment marks 310 previously provided on the base 14.

FIG. 20 is a block diagram of the film-forming apparatus 300. The control system of the film-forming apparatus 300 comprises a host computer 311 for performing the whole control, a control unit 312 of the stage 301, a control unit 313 of the discharge head 304 for performing the ejection of material, an image processing unit 314 for performing a detection of existence and non-existence of the ejection from the discharge head 304 or a measurement of an arranged position of material or a position of the patterning area in accordance with the image data read out by the sensor 305, and a posture adjusting control unit 315 for controlling a posture and a position of the discharge head 304.

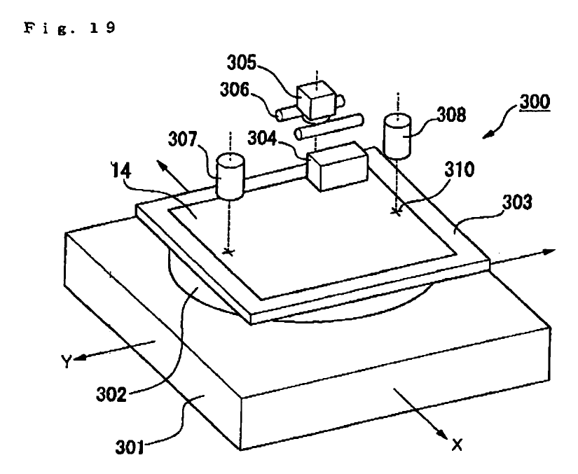

FIG. 21 is a view illustrating in detail arrangements of the discharge head 304, the sensor 305 and the light source 306 described in FIG. 19. The discharge head 304 is constructed to adjust its posture by means of a θ direction adjusting mechanism 325, a Z direction adjusting mechanism 326 and an Y direction adjusting mechanism 327, and a gap between the discharge head 304 and the base 14 can be set to a predetermined distance by means of the Z direction adjusting mechanism 326. Further, the θ direction adjusting mechanism 325 can set the discharge head 304 to a predetermined angle about the base 14. The posture adjusting mechanisms 325, 326, 327 constitute Y, Z and θ axes by combination of moving mechanisms such as a translational stage and the rotational stage. Furthermore, the moving mechanism of each axis may be constructed to be operated manually, and may be constructed to be operated by attaching a driving source such as a motor or the like. The discharge head 304 has a plurality of material ejecting outlet (nozzles) and is arranged in the Y direction of the drawing.

Furthermore, in the image pickup element 319 such as a CCD line sensor, an image on a straight line connecting two points A and B on the base 14, irradiated by the light source 306, is imaged by means of a lens 322. The image pickup element 319 is constructed to adjust its posture by means of the θ direction adjusting mechanism 320 and the Z direction adjusting mechanism 321. The relative position relations of the base 14, the discharge head 304 and the image pickup element 319 can be moved in the X, Y and θ directions of the drawing by means of the moving mechanisms 301 and 302 in FIG. 19.

Next, operations of the film-forming apparatus according to this embodiment will be described.

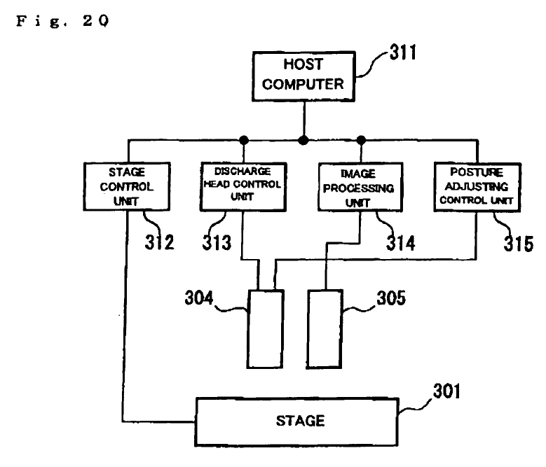

FIG. 22 is a flowchart for explaining the operations of the film-forming apparatus 300. First, the base 14 which is a subject for arranging material in the film-forming apparatus 300 is provided on the fixed board 303 of FIG. 19 (step S11). The provided base 14 is fixed by absorbing means such as electrostatic absorption or the like (step S12). Next, the alignment marks 310 formed on the base 14 are read out by the sensors 307, 308 (step S13). The position of the base 14 is calculated from the read-out alignment marks, and alignment of the base 14 is performed using the moving mechanisms 301, 302 of FIG. 18 (step S14). If the alignment of the base 14 is finished, the preliminary ejection is performed (step S15). The preliminary ejection is performed to a margin (a preliminary-ejecting area) on the base 14, which is a subject for arranging materials. By performing the preliminary ejection before arranging the material in the patterning area, it is possible to always stabilize the ejecting state, and even if non-ejection occurs or the arranged position of material is deviated, it can be previously detected and thus it is possible to suppress generation of defectives.

Next, the preliminary ejection pattern in which the material is arranged and the arranging pattern formed in the patterning area are read out by the sensor 305 (step S16). The non-ejection is checked from the read-out preliminary ejection pattern (step S17). Specifically, the check is performed by processing the image data reading out whether the material from the nozzles to be used for the ejection of materials is landed as dots on the base 14 and exists. If the non-ejection from a nozzle used is detected, it is checked whether a nozzle usable in place of the used nozzle exists or not (step S18). When a usable nozzle does not exist, the discharge head 304 is exchanged with a new discharge head (step S28). In the step S18, when a usable nozzle exists, the used nozzle is exchanged (step S19), the deposition of the head is moved by means of the adjusting mechanisms (step S20) such that a position of the newly changed nozzle comes in the position of the nozzle used until now.

When the non-ejection is not detected in the step S17, positions of dots in the preliminary ejection pattern and positions of the arranging pattern are calculated in accordance with the read-out image data (steps S21, S22). Next, the deviated amount between the positions of dots and the positions of the arranging pattern is calculated (step S23). Here, if the deviated amount calculated in the step S23 exceeds the allowable range to cause difficulty in arranging the material in the patterning area, correction of the deviated amount is performed in the step S25 (step S24). In the step S24, if the deviated amount calculated in the step S23 falls within the allowable range, the correction may not be performed. At that time, since the material arrangement in the patterning area becomes possible, the arrangement of material is performed (step S26) to form a film on the base 14. If the formation of film is finished, the base 14 is taken out, and thus one cycle for forming a film is finished (step S27).

Thus, according to this embodiment, by performing the preliminary ejection in the outside of the patterning area of the base, it is possible to improve the stability of the material ejection and it is also possible to correct the deviation between the discharge head and the arranging pattern.

Furthermore, the aforementioned embodiment can be changed or modified without departing from the subject matter of the present invention.

For example, the pattern for confirming the ejection from the nozzles is not limited only if the ejection and the non-ejection can be confirmed. In this case, an area sensor camera may be used if the area sensor camera is suitable depending upon the pattern. Furthermore, even when the preliminary-ejecting area is one area on the base or a specific area in the outside of the base, the effects that the generation of defectives can be suppressed in minimum can be obtained similarly.

Furthermore, in the above embodiment, although it is described that the discharge head and the line sensor camera are fixed and the X, Y and θ stage sides are moved, the stage sides may be fixed and the discharge head and the line sensor camera sides may be moved. Furthermore, in the above embodiment, although the detection of abnormality such as non-ejection of the discharge head is performed using the television camera and the image processing unit, the present invention is not limited to these, but the detection of abnormality may be performed by means of detection of interference fringes when a laser beam passes through the material. Furthermore, the detection of abnormality may be performed by detecting the light-reflectivity or the light-transmissivity of a head abnormality detecting pattern arranged.

[Fifth Embodiment]

Next, an embodiment in which an electro-optical device of the present invention applies to an active matrix type display device using organic EL elements will be described.

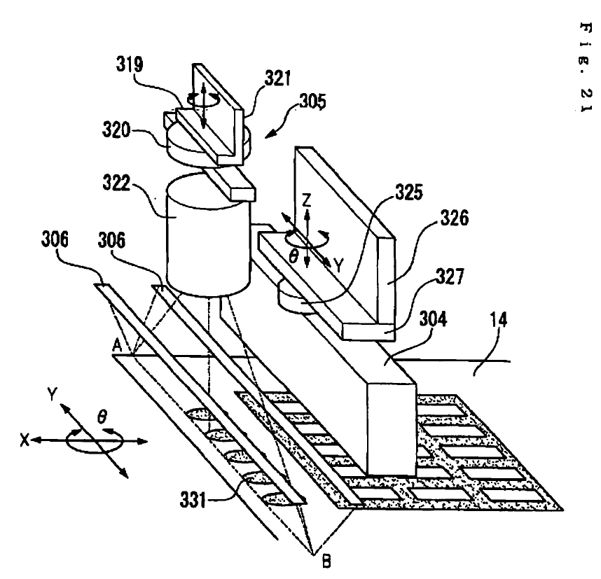

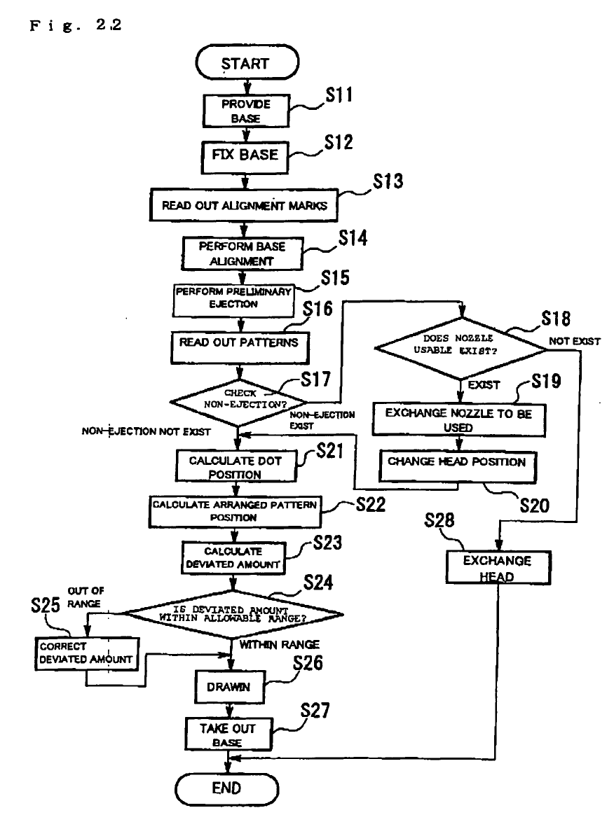

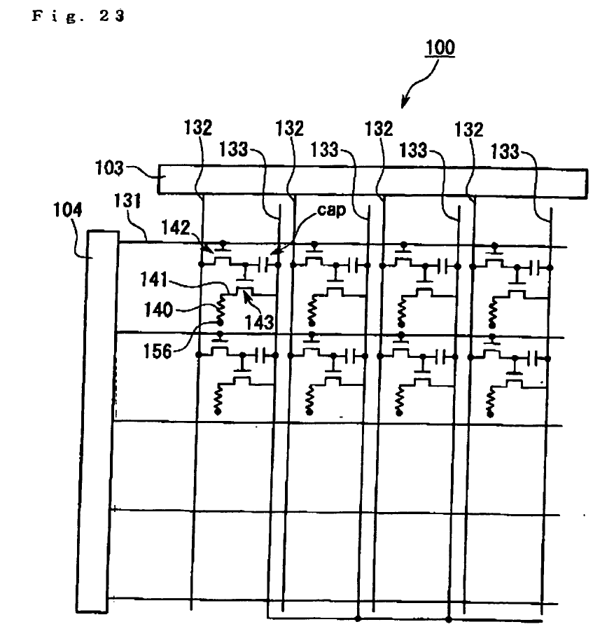

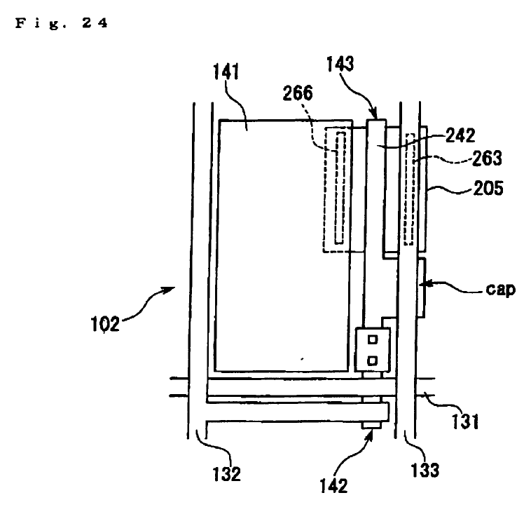

FIG. 23 illustrate an example of circuits of the active matrix type organic EL display device of this embodiment, and FIG. 24 illustrates an example of a planar structure of a pixel unit in the display device of this embodiment.

The display device 100 of this embodiment is characterized in that a part of elements thereof are formed using any one of the film-forming apparatus described above.

In the display device 100, as shown in FIG. 24, a plurality of scanning lines 131, a plurality of signal lines 132 extending in a direction intersecting the scanning lines 131, and a plurality of common current supply line 133 extending in parallel to the signal lines 132 are wired on a substrate as the base, and a pixel (pixel area) 102 is provided every intersection of the scanning lines 131 and the signal lines 132.

For the signal lines 132, a data side driving circuit 103 including, for example, a shift register, a level shifter, video lines, and an analog switch is provided. On the other hand, for the scanning lines 131, a scanning side driving circuit 104 including a shift register and a level shifter is provided. Furthermore, each of the pixel areas 102 is provided with a first thin film transistor 142 in which a scanning signal is transmitted to its gate electrode through the scanning lines 131, a holding capacitor cap for holding the image signal transmitted from the signal lines 132 through the first thin film transistor 142, a second thin film transistor 143 in which the image signal held by the holding capacitor cap is transmitted to its gate electrode, a pixel electrode 141 (anode) to which the driving current flows from the common current supply lines 133 when being electrically connected to the common current supply lines 133 through the second thin film transistor 143, and a light emitting portion 140 disposed between the pixel electrode 141 and a counter electrode 154 (cathode).

Furthermore, as shown in FIG. 24, in the planar structure of each pixel 102, four sides of the pixel electrode 141 having a rectangular planar shape are surrounded with the signal line 132, the common current supply line 133, the scanning line 131, and other scanning line for other pixel electrode as not shown. The planar shape of the pixel area 102 may be any shape such as a circle, an ellipse or the like, in addition to a rectangle shown in the drawing.

Under this construction, when the scanning line 131 is driven and thus the first thin film transistor 142 is turned on, a potential of the signal line 132 at that time is held by the holding capacitor cap, the conduction state of the second thin film transistor 143 is determined in accordance with the states of the holding capacitor cap. Then, a current flows from the common current supply line 133 to the pixel electrode 141 through a channel of the second thin film transistor 143, and the current flows through the light emitting portion 140 to the counter electrode 154, so that the light emitting portion 140 emits a light in accordance with the current amount flowing through it.

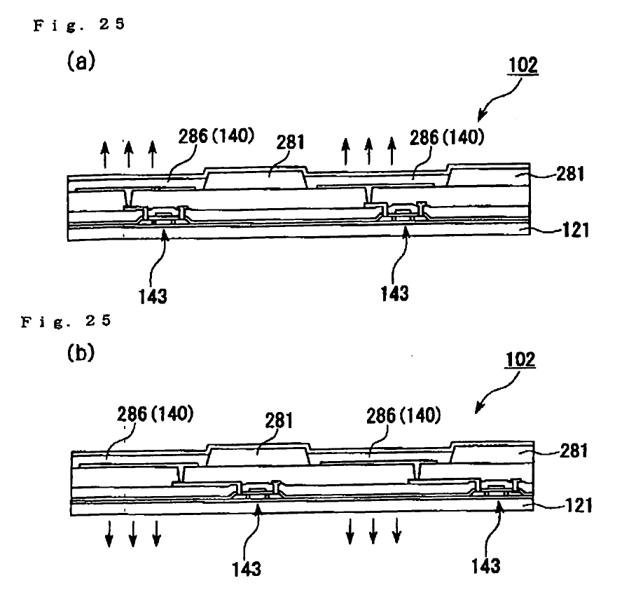

FIGS. 25(a) and 25(b) schematically illustrate a cross-sectional structure of the pixel unit 102 (organic EL element), wherein FIG. 25(a) shows a so-called top emission type and FIG. 25(b) shows a so-called back emission type. In FIG. 25(a), in the top emission type EL element, the light emitted from the light-emitting layer 286 (EL layer, light emitting portion 140) is extracted from the side of the substrate 121 opposite that on which the thin film transistor 143 is provided. For this reason, the substrate 121 may be transparent and may be opaque. The opaque substrate includes a thermosetting resin, a thermoplastic resin or the like, in addition to a substrate obtained by performing an insulating process such as a surface oxidation to a ceramic such as alumina or the like, a metal sheet such as stainless or the like.

In FIG. 25(b), in the back emission type EL element, the light emitted from the light-emitting layer 286 is extracted from the substrate 121 side on which the thin film transistor 143 is provided. For this reason, as the substrate 121, a transparent or semitransparent substrate is used. The transparent or semitransparent substrate includes a glass substrate, a quartz substrate, a resin substrate (a plastic substrate, a plastic film substrate, etc.), and specifically an inexpensive soda lime glass substrate can be suitably used. Furthermore, when the soda lime glass substrate is used, by performing a silica coating to it, the soda lime glass susceptible to acid-alkali is protected and also the planarity of the substrate is improved. Furthermore, by providing on the substrate a color filter film or a color converting film including luminescent material or a derivative reflecting film, the light emitting color may be controlled.

Furthermore, in FIG. 25(b), the reference numeral 281 denotes a bank layer having a partition for preventing the light-emitting layers adjacent to each other from being mixed at the time of forming the light-emitting layer 286 (EL layer). Herein, although the bank layer has a taper structure in which the top length thereof is smaller than the bottom length thereof, the bank layer may have a structure in which the top length is equal to or lager than the bottom length, to the contrary. In the back emission type EL element, since the light emitted from the light-emitting layer 286 is extracted from the substrate 121 side on which the thin film transistor 143 is provided, it is preferable that the thin film transistor 143 be provided under the bank layer 281, not right below the light-emitting layer 286, for the purpose of efficiently extracting the light.

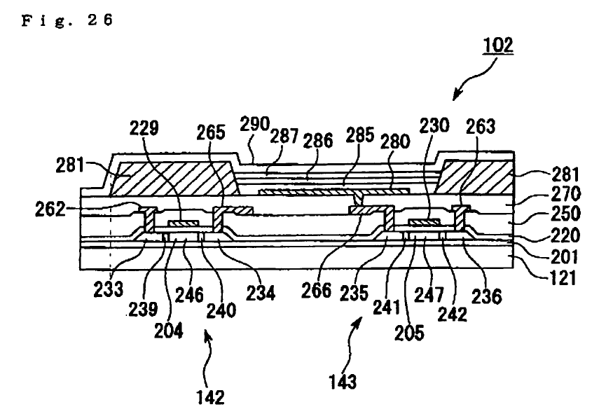

FIG. 26 illustrates an enlarged cross-sectional structure of the top emission type pixel unit 102 (organic EL element).

In FIG. 26, the organic EL element comprises a substrate 121, an anode 280 (pixel electrode) made of transparent electrode material such as indium tin oxide (ITO) or the like, a hole-transporting layer 285 for transporting holes from the anode 280, a light-emitting layer 286 (organic EL layer) including organic EL material which is one of electro-optical materials, an electron-transporting layer 287 provided on a top surface of the light-emitting layer 286, a cathode 290 (a counter electrode) provided on a top surface of the electron-transporting layer 287, and thin film transistors 142, 143 as an current flow control unit formed on the substrate 121 for controlling whether data signals are written to the pixel electrode 280. The cathode 290 is formed to cover the whole surface of the element, and forms a pair together with the pixel electrode 280 to serve for injecting electrons into the light-emitting layer 286. The cathode 290 may have a single-layer structure and may have a multi-layer structure. Furthermore, a material for forming the cathode 290 can include lithium fluoride, etc. in addition to aluminum (Al), magnesium (Mg), gold (Au), silver (Ag), and calcium (Ca). These materials may be used individually and may be used as an alloy.

The thin film transistors 142, 143 are all n channel type in this embodiment. Furthermore, the thin film transistors 142, 143 are all not limited to the n channel type TFT, but both or any one thereof may use a p channel type thin film transistor.

The thin film transistors 142, 143 are provided on a surface of the substrate 121 through a base protective film 201 containing SiO₂ as a main component, and comprises semiconductor films 204, 205 made of silicon and formed on the base protective film 201, a gate insulating film 220 provided on the base protective film 201 to cover the semiconductor films 204, 205, gate electrodes 229, 230 provided in portions on the gate insulating film 220 which is opposed to the semiconductor films 204, 205, a first interlayer insulating film 250 provided on the gate insulating film 220 to cover the gate electrodes 229, 230, source electrodes 262, 263 connected to the semiconductor films 204, 205 through contact holes opened across the gate insulating film 220 and the first interlayer insulating film 250, drain electrodes 265, 266 provided on positions opposed to the source electrodes 262, 263 through the gate electrodes 229, 230 and connected to the semiconductor films 204, 205 through contact holes opened across the gate insulating film 220 and the first interlayer insulating film 250, and a second interlayer insulating film 270 provided on the first interlayer insulating film 250 to cover the source electrodes 262, 263 and the drain electrodes 265, 266.

Furthermore, the pixel electrode 280 is provided on the second interlayer insulating film 270, and the pixel electrode 280 and the drain electrode 266 are connected to each other through the contact holes provided in the second interlayer insulating film 270. Furthermore, a third insulating layer (bank layer) 281 made of synthetic resin or the like is provided between the cathode 290 and portions of a surface of the second interlayer insulating film 270 in which the organic EL element is not provided.

Furthermore, when the materials of the first interlayer insulating film 250 and the second interlayer insulating film 270 are different from each other, as shown in the drawing, it is preferable that the contact holes provided in the first interlayer insulating film 250 and the contact holes 275 provided in the second interlayer insulating film 270 be formed not to overlap each other.

Furthermore, regions of the semiconductor films 204, 205 overlapping the gate electrodes 229, 230 through the gate insulating film 220 serve as channel regions 246, 247. Furthermore, source regions 233, 236 are provided on the source sides of the channel regions 246, 247 in the semiconductor films 204, 205, while drain regions 234, 235 are provided on the drain sides of the channel regions 246, 247. Among them, the source regions 233, 236 are connected to the source electrodes 262, 263 through the contact holes opened across the gate insulating film 220 and the first interlayer insulating film 250. On the other hand, the drain regions 234, 235 are connected to the drain electrodes 265, 266 made of the same layer as the source electrodes 262, 263 through the contact holes opened across the gate insulating film 220 and the first interlayer insulating film 250. The pixel electrode 280 is electrically connected to the drain region 235 of the semiconductor film 205 through the drain electrode 266.

In the organic EL element of this embodiment, the hole-transporting layer 285, the light-emitting layer 286 and the electron-transporting layer 287 are formed using the aforementioned film-forming apparatus. For this reason, the degree of freedom in selection of materials for forming these layers is high. Furthermore, when forming these layers, it is possible to avoid use of solvent or to decrease the use amount of solvent, and as a result, it is possible to avoid disadvantages due to residual of solvent such as deterioration of layers, etc. Furthermore, in addition to the hole-transporting layer 285, the light-emitting layer 286, and the electron-transporting layer 287, other films may be formed using the aforementioned film-forming apparatus.

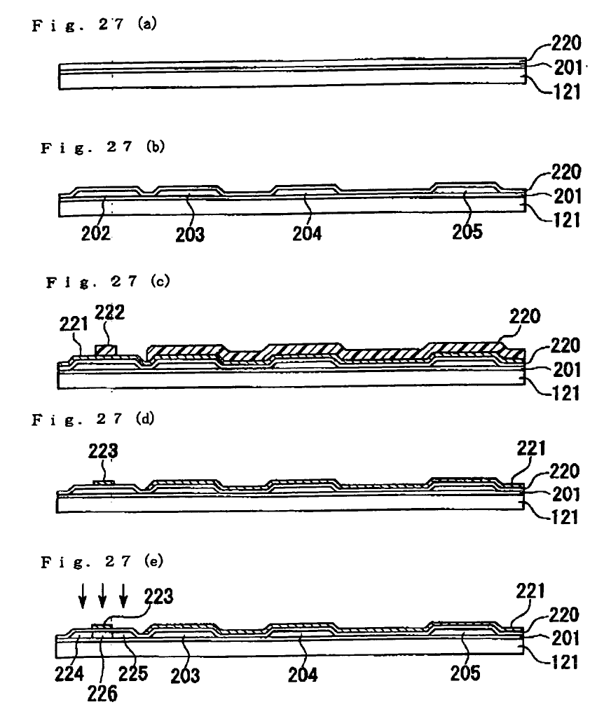

Next, embodiments in which the method of manufacturing the electro-optical device according to the present invention applies to the processes of manufacturing the display device comprising the aforementioned organic EL element will be described with reference to FIGS. 27 to 30. Furthermore, in this embodiment, a process of manufacturing the organic EL element including the aforementioned thin film transistors 142, 143 and N type and P type thin film transistors for the driving circuits at the same time will be described.

First, as shown in FIG. 27(a), a base protective film 201 made of silicon oxide films having a thickness of about 200 to 500 nm is formed on the substrate 121 by means of a plasma CVD method using TEOS (tetraethoxysilane) or oxygen gas as a raw material as needed. Furthermore, as the base protective film, a silicon nitride film or silicon oxy-nitride film may be provided in addition to the silicon oxide film. By providing such insulating film, the radiation can be enhanced.

Next, the temperature of the substrate 121 is set to about 350° C., and a semiconductor film 200 made of amorphous silicon film and having a thickness of about 30 to 70 nm is formed on the surface of the base protective film using an ICVD method, the plasma CVD method or the like. As the semiconductor film 200, a semiconductor film comprising the amorphous structure such as microcrystal semiconductor film or the like may be provided in addition to the amorphous silicon film. Furthermore, a compound semiconductor film comprising amorphous structure such as amorphous silicon germanium film or the like may be provided.

Subsequently, a crystallizing process such as a laser anneal method or a rapid heating method (a lamp anneal method or a heat anneal method) is carried out to the semiconductor film 200, to crystallize the semiconductor film 200 into a poly silicon film. In the laser anneal method, for example, a line beam in which a long size of a beam in the excimer laser is 400 mm is used and the output intensity thereof is, for example, 200 mJ/cm². Furthermore, second harmonics or third harmonics of YAG laser may be used. For the line beam, it is preferable that the line beam be scanned such that a portion corresponding to 90% of a peak value of the laser intensity in a short size direction is overlapped for every regions.

Next, as shown in FIG. 27(b), by removing unnecessary portions of the semiconductor film (poly silicon film) 200 by means of a patterning using a photolithography method or the like, island-shaped semiconductor films 202, 203, 204, 205 corresponding to the respective forming areas of thin film transistors are formed.

Subsequently, a gate insulating film 220 made of silicon oxide film or nitride film (silicon oxy-nitride film, etc.) having a thickness of about 60 to 150 nm is formed to cover the semiconductor film 200 by means of the plasma CVD method using TEOS or oxygen gas as a raw material. The gate insulating film 220 may have a single-layer structure and may have a stacked structure. Furthermore, other method such as thermal oxidation method or the like may be used in addition to the plasma CVD method. Furthermore, when forming the gate insulating film 220 by use of the thermal oxidation method, the crystallization of the semiconductor film 200 can be also performed to convert the semiconductor film into a poly silicon film.

Next, as shown in FIG. 27(c), a conductive film 221 for forming the gate electrode including doped silicon, silicide film, or metal such as aluminum, tantalum, molybdenum, titanium, tungsten or the like is formed on the whole surface of the gate insulating film 220. A thickness of this conductive film 221 is about 200 mn.

Subsequently, a patterning mask 222 is formed on the surface of the conductive film 221 for forming the gate electrode, and by performing the patterning in this state, as shown in FIG. 27(d), a gate electrode 223 is formed on an area in which a P type transistor for the driving circuit would be formed. At that time, on the areas in which the N type transistor for pixel electrode and the N type transistor for the driving circuit exist, since the conductive film 221 for forming the gate electrode is covered with the patterning mask 222, the conductive film 221 for forming the gate electrode is not patterned. Furthermore, the gate electrode may be formed with a single-layer conductive film and may have a stacked structure.

Next, as show in FIG. 27(e), using the gate electrode 223 of the P type transistor for driving circuit and the conductive film 221 for forming the gate electrode remaining in the area in which the N type transistor for pixel electrode would be formed and the area in which the N type transistor for driving circuit would be formed as a mask, p type impurity element (boron in this embodiment) is ion-implanted. The dose amount thereof is for example, about 1×10¹⁵ cm⁻². As a result, highly-doped source/drain regions 224, 225 the impurity concentration of which is, for example, about 1×10²⁰ cm⁻³ are formed in a manner self-aligned with respect to the gate electrode 223. Here, a portion which is covered with the gate electrode 223 and into which the impurities are not introduced becomes the channel region 226.

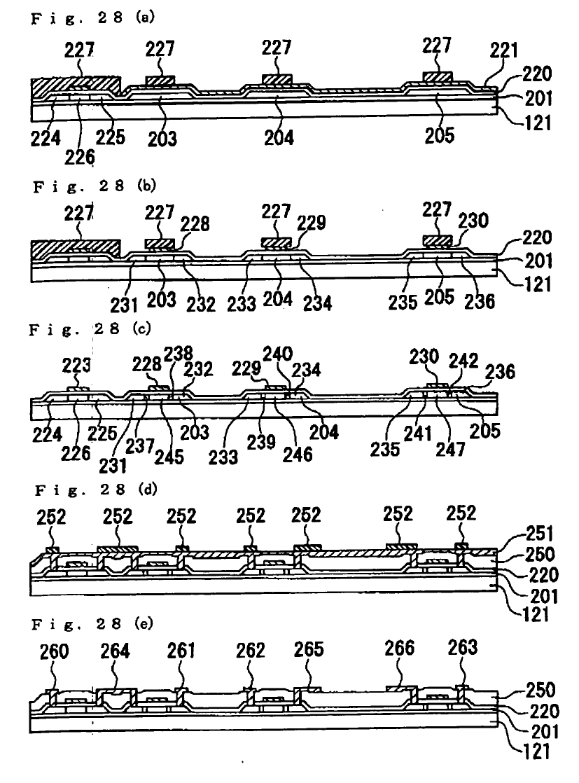

Next, as shown in FIG. 28(a), a patterning mask 227 made of resist mask entirely covering the P type transistor for driving circuit and covering the area for forming the gate electrode on sides of the N type TFT 10 for pixel electrode and the N type transistor for driving circuit is formed.

Next, as shown in FIG. 28(b), the conductive film 221 for forming the gate electrode is patterned using the patterning mask 227 to form the gate electrodes 228, 229, 230 of the N type transistor for pixel electrode and the N type transistor for driving circuit.

Subsequently, n type impurity elements (phosphorus in this embodiment) are ion implanted with the patterning mask 227 remained. The dose amount thereof is, for example, about 1×10¹⁵ cm⁻². As a result, impurities are introduced into the patterning mask 227 in a self aligned manner, and a highly-doped source and drain regions 231, 232, 233, 234, 235, 236 are formed in the semiconductor films 203, 204, 205. Here, an area of the semiconductor films 203, 204, 205 into which high-concentration phosphorus is not introduced is larger than the regions covered with the gate electrodes 228, 229, 230. That is, on both sides of the regions in the semiconductor films 203, 204, 205 opposed to the gate electrodes 228, 229, 230, regions (lowly doped source and drain regions described later) into which the high-concentration phosphorus is not introduced are formed between the gate electrodes and the highly doped source and drain regions 231, 232, 233, 234, 235, 236.

Next, the patterning mask 227 is removed, and in this state, n type impurity element (phosphorus in this embodiment) is ion implanted. The dose amount thereof is, for example, 1×10¹³ cm⁻². As a result, as shown in FIG. 28(c), in the semiconductor films 203, 204, 205, the low-concentration impurities are introduced into the gate electrodes 228, 229, 230 in the self-aligned manner, to form the lowly doped source and drain regions 237, 238, 239, 240, 241, 242. Furthermore, the impurities are not introduced into the regions overlapping the gate electrode 228, 229, 230, to form the channel regions 245, 246, 247.

Next, as shown in FIG. 28(d), by forming the first interlayer insulating film 250 on the surface side of the gate electrodes 228, 229, 230 and patterning the first interlayer insulating film using the photolithography method, the contact holes are formed in predetermined source electrode positions and drain electrode positions. As the first interlayer insulating film 250, for example, an insulating film including silicon such as silicon oxy-nitride film or silicon oxide film may be used. Furthermore, the first interlayer insulating film may be single-layer and may be stacked-film. Furthermore, by performing the heat treatment in an atmosphere containing hydrogen, an unpaired bonding of the semiconductor film is hydrogen-terminated (hydrogenated). Furthermore, the hydrogenation may be performed using hydrogen excited by plasma.

Subsequently, a conductive film 251 which would be source electrodes and drain electrodes is formed using metal film such as aluminum film, chrome film, tantalum film or the like. A thickness of the conductive film 251 is, for example, about 200 nm to 300 nm. The conductive film may have a single layer structure and may have a stacked structure.

Subsequently, by forming the patterning mask 252 at positions of source electrodes and drain electrodes and also performing the patterning, the source electrodes 260, 261, 262, 263 and the drain electrodes 264, 265, 266 shown in FIG. 28(e) are formed at the same time.

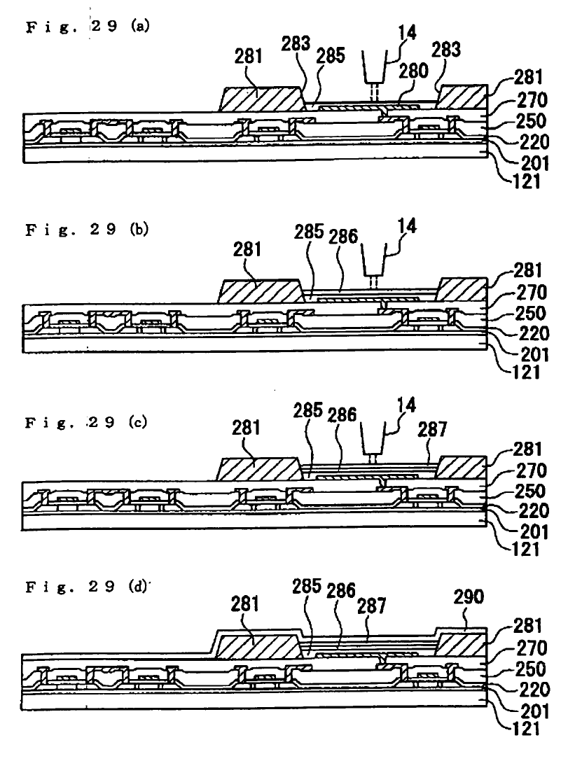

Next, as shown in FIG. 29(a), the second interlayer insulating film 270 made of silicon nitride or the like is formed. A thickness of the second interlayer insulating film 270 is, for example, about 1 to 2 μm. As a material for forming the second interlayer insulating film 270, a material capable of transmitting light such as silicon oxide film, organic resin, silica aero-gel or the like is used. As the organic resin, acryl, polyimide, polyamide, BCB (benzocyclobutene) or the like can be used.

Next, as shown in FIG. 29(b), by etching and removing the second interlayer insulating film 270, a contact hole 275 reaching in the drain electrode 266 is formed.

Next, as shown in FIG. 29(c), a film made of SnO₂ obtained by doping for example, ITO or fluorine and transparent electrode materials such as ZnO or polyaniline or the like is formed to fill in the contact hole 275, and the pixel electrode 280 electrically connected to the source and drain regions 235, 236 is formed. Furthermore, the pixel electrode 280 serves as the anode of the EL element.

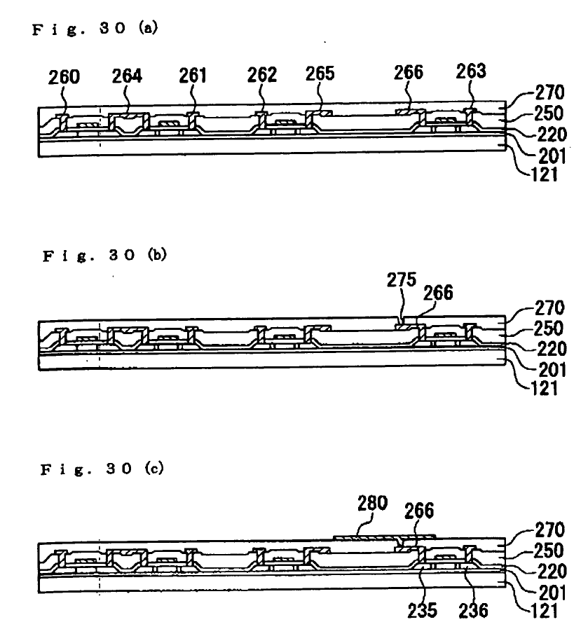

Next, as shown in FIG. 30(a), a third insulating layer (bank layer) 281 is formed to sandwich the pixel electrode 280. Specifically, an insulating layer is formed by applying a solution obtained by dissolving resists such as acryl resin, polyimide resin or the like in a solvent by use of a spin coat method, a deep coat method, and the insulating layer is concurrently etched by use of the photolithography technology or the like. As the third insulating layer 281, synthetic resin such as acryl resin, polyimide resin or the like is used. Furthermore, the bank layer including signal lines, common current supply lines, scanning lines or the like may be formed.

Subsequently, the hole-transporting layer 285 is formed to cover the pixel electrode 280.

In this embodiment, the hole-transporting layer 285 is formed using the aforementioned film-forming apparatus. That is, a substrate 121 is disposed in the vacuum chamber controlled to a vacuum pressure, and the material for forming the hole-transporting layer 285 is discharged from a nozzle 14 toward the substrate 121. At that time, the material for forming the hole-transporting layer 285 may be gasified and discharged from the nozzle 14. The gasified material is cooled by heat exchange after reaching the substrate 121, and is liquefied or solidified and then fixed. Then, by arranging a predetermined amount of material on the substrate 121, the hole-transporting layer 285 is formed on the base 11.

Furthermore, when the material is liquefied on the substrate 121, the material is to be diffused horizontally due to its fluidity, but the diffusion is prevented by means of the partition of the third insulating layer (bank layer). Furthermore, when disadvantages due to fluidity of material do not occur in accordance with the processing condition or characteristic of material, the height of the third insulating layer may be decreased or the partition may not be used. Furthermore, after the material is discharged from the nozzle 15 to the substrate 121, the substrate 121 is once taken out of the vacuum chamber, and then the material may be solidified or hardened by performing the process such as heating or light irradiation as needed.

The material for forming the hole-transporting layer 285 is not particularly limited, and can include the well-known materials such as pyrazoline derivatives, arylamine derivatives, stilbene derivatives, triphenyldiamine derivatives or the like. Specifically, although materials disclosed in Japanese Unexamined Patent Application Publication Nos. 63-70257, 63-175860, 2-135359, 2-135361, 2-209988, 3-37992, and 3-152184 can be exemplified, triphenyldiamine derivatives is preferable and among them 4,4′-bis (N(3-methylphenyl)-N-phenylamino) biphenyl is more preferable.

Furthermore, a hole-injecting layer may be formed in place of the hole-transporting layer, and the hole-injecting layer and the hole-transporting layer may be all formed. In this case, the material for forming the hole-injecting layer can include copper phthalocyanine (CuPc), polyphenylenevinylene which is polytetrahydrothiophenylphenylene, 1,1-bis-(4-N,N-ditrilaminophenyl) cyclohexane, tris(8-hydroxyquinorinol) aluminum or the like, but it is preferable that copper phthalocyanine (CuPc) be used. When the hole-injecting layer and the hole-transporting layer are all formed, it is preferable that the hole-injecting layer be formed on the pixel electrode side previously to the formation of the hole-transporting layer and the hole-transporting layer be formed thereon. Thus, by forming the hole-injecting layer together with the hole-transporting layer, it is possible to control increase in the driving voltage and also to lengthen the driving life span (half life).

Next, as shown in FIG. 30(b), a light-emitting layer 286 is formed on the hole-transporting layer 285.

In this embodiment, similarly to the aforementioned hole-transporting layer (and/or the hole-injecting layer), the light-emitting layer 286 is formed using the aforementioned film-forming apparatus. That is, the substrate 121 is disposed in the vacuum chamber controlled to a vacuum pressure and the material for forming the light-emitting layer 286 is discharged from the nozzle 15 toward the substrate 121.

The material for forming the light-emitting layer 286 is not particularly limited, and can include low-molecular organic light emitting pigment or high-molecular light emitting material, that is, light emitting materials comprising various fluorescent materials or phosphorescent material. It is specifically preferable that conjugate base polymers constituting the illuminant material includes arylenevinylene structure. The low-molecule fluorescent materials include, for example, naphthalene derivatives, anthracene derivatives, perylene derivatives, colorant base such as polymethine base, quisatene base, coumarine base, cyanine base, etc., metal complex of 8-hydroquinoline and its derivatives, aromatic amine, tetraphenylcyclopentadiene derivatives, or well-known materials disclosed in Japanese Unexamined Patent Application Publication Nos. 57-51781 and 59-194393.

Next, as shown in FIG. 30(c), the electron-transporting layer 287 is formed on the light-emitting layer 286.

In this embodiment, similarly to the hole-transporting layer 285 and the light-emitting layer 286, the electron-transporting layer 287 is formed using the aforementioned film-forming apparatus. That is, the substrate 121 is disposed in the vacuum chamber controlled to a vacuum pressure, and then the material for forming the electron-transporting layer 287 is discharged from the nozzle 15 toward the substrate 121.

The materials for forming the electron-transporting layer 287 is not particularly limited, and for example, include metal complex of oxadiazol derivatives, anthraquinodimethan and its derivatives, benzoquinone and its derivatives, naphthoquinone and its derivatives, anthraquinone and its derivatives, tetracyano anthraquinodimethan and its derivatives, fluorenone derivatives, diphenyldicyano ethylene and its derivatives, diphenoquinone derivatives, 8-hydroxyquinoline and its derivatives, etc. More specifically, similarly to the materials for forming the hole-injecting layer, the materials for forming the electron-transporting layer may include materials disclosed in Japanese Unexamined Patent Application Publication Nos. 63-70257, 63-175860, 2-135359, 2-135361, 2-209988, 3-37992, and 3-152184. In particular, 2-(4-biphenylyl)-5-(4-t-(butyl phenyl)-1,3,4-oxadiazol, benzoquinone, anthraquinone, and tis(8-quinolinol) aluminum are suitable.

Further, materials formed by mixing the material for forming the hole-transporting layer 285 or the material for forming the electron-transporting layer 287 with the material for forming the light-emitting layer 286 may be used as the material for forming the light-emitting layer. In this case, the used amount of the material for forming the hole-transporting layer or the material for forming the electron-transporting layer is different from each other depending on the types of the used compounds, but the used amount is properly determined in consideration of the types of the used compounds within the range in which the sufficient capability for forming films and characteristics in light emitting are not deteriorated. Generally, the materials for forming the light-emitting layer have 1 to 40 wt % and more preferable, 2 to 30 wt %.

Furthermore, each film thickness of the hole-transporting layer 285, the light-emitting layer 286, and the electron-transporting layer 287 described above is formed to have a preferable thickness (for example, 65 nm) by properly setting the discharged amount of the respective forming materials from the nozzle 14 in advance. Furthermore, by promoting movement of the materials from the nozzle 15 or gasifying and discharging the materials from the nozzle 15 using the pressure difference, the forming materials can be arranged on the substrate without dissolving the forming materials in a solvent, or with decreasing the used amount of solvent.

For this reason, it is possible to avoid the disadvantages such as deterioration of material due to residual of solvent.

Next, as shown in FIG. 30(d), a counter electrode 290 is formed as a cathode on the entire surface of the substrate 121 or in a stripe shape. The counter electrode 290 may be formed as a single layer comprising a simple material such as Al, Mg, Li, Ca or the like or an alloy material of Mg:Ag (10:1 alloy), or as a metal (including alloys) layer having two-layer structure or three-layer structure. Specifically, a stacked film such as Li₂O (about 0.5 nm)/Al or LiF (about 0.5 nm)/Al, MgF₂/Al or the like can be included.

Through the above processes, the organic EL element and the N type and P type thin film transistors for driving circuit are completed.

Furthermore, in the aforementioned embodiment, although the hole-transporting layer 285, the light-emitting layer 286, and the electron-transporting layer 287 are formed using the aforementioned film-forming apparatus, other layers may be formed using the film-forming apparatus, similarly. For example, the pixel electrode 280 (anode) or the counter electrode 290 (cathode) may be formed using the aforementioned film-forming apparatus. That is, a transparent electrode (anode) made of indium tin oxide (ITO), tin oxide (SnO₂), zinc oxide (ZnO) or the like, or a cathode having a stacked structure such as Al/Ca or the like may be formed using the film-forming apparatus 10.

Furthermore, specifically in the process of forming transistors shown in FIGS. 27 and 28, any layer may be formed using the aforementioned film-forming apparatus. Specifically, by discharging the gasified material to form a layer, it is possible to control the film thickness with a high accuracy. For this reason, a high accurate transistor can be formed. Furthermore, since the materials can be arranged at desired positions by using the aforementioned film-forming apparatus, it is possible to omit or decrease use of masks.

FIG. 31 illustrates another example of the organic EL element.

The organic EL element shown in FIG. 31 has a sealing layer (at least one of first sealing layer 295, second sealing layer 296, and third sealing layer 297) for preventing gas or metal ions from being injected, unlike the aforementioned examples.

The first sealing layer 295 is formed to cover the source electrodes 262, 263 and the drain electrodes 265, 266 between the first interlayer insulating film 250 and the second interlayer insulating film 270, and the film thickness thereof is, for example, 50 to 500 nm. As a material constituting the first sealing layer 295, for example, materials such as ceramic, silicon nitride, silicon oxy-nitride, silicon oxide or the like are used. The first sealing layer 295 prevents moisture or alkali metals (sodium) from the light-emitting layer 286 (EL layer), etc. from being infiltrated into the thin film transistors 142, 143.

Furthermore, as the material constituting the first sealing layer 295, a material having radiation effects may be used in addition to the sealing effect of the alkali metal. These materials include an insulating film comprising, for example, at least one element of B (boron), C (carbon) and N (nitrogen) and at least one element of Al (aluminum), Si (silicon) and P (phosphorus). For example, aluminum nitride, silicon carbide, silicon nitride, boron nitride, boron phosphide or the like can be used. Furthermore, the insulating film including Si, Al, N, O, M (where M is at least one of rare earth elements, and preferably at least one element of Ce (cerium), Yb (ytterbium), Sm (samarium), Er (erbium), Y (yttrium), La (lanthanum), Gb (gadolinium), Dy (dysprosium) and Nd (neodymium)) may be used. Furthermore, a diamond thin film or a carbon film including amorphous carbon film (diamond-like carbon, etc.) may be used. These have high heat conductivity and thus have a high radiation effect.

The second sealing layer 296 is formed between the second interlayer insulating film 270 and the pixel electrode 280, and the film thickness thereof is, for example, 50 to 500 nm. As a material constituting the second sealing layer 296, for example, materials such as ceramics, silicon nitride, silicon oxy-nitride, silicon oxide or the like are used. The second sealing layer 296 prevents moisture or alkali metals (sodium) from the light-emitting layer 286 (EL layer), etc. from being infiltrated into the thin film transistors 142, 143. As the material constituting the second sealing layer 296, the materials used for the first sealing layer described above can be used. Furthermore, the radiation effect may be added in addition to the sealing effect of the alkali metal.

The third sealing layer 297 is formed to cover the cathode 290, and the film thickness thereof is, for example, 50 to 500 nm. As a material constituting the third sealing layer 297, for example, materials such as ceramics, silicon nitride, silicon oxy-nitride, silicon oxide or the like are used. The third sealing layer 297 prevents infiltration of moisture from the outside. As the material constituting the third sealing layer 297, the materials used for the first sealing layer described above can be used. Furthermore, the radiation effect may be added in addition to the sealing effect of the alkali metal. Furthermore, the organic EL element of FIG. 31 is the top emission type, and thus it is preferable that the third sealing layer 297 is formed to have a material and a thickness for well transmitting light.

Furthermore, in place of or in addition to such sealing layers, a low refractive layer may be formed to improve the extracting efficiency of light. The low refractive layer is a layer having light-transmission refractive index lower than that of the substrate, and is made of for example, silica aero-gel. The silica aero-gel is a light-transparent porous substance having a uniform hyperfine structure obtained by supercritically drying wet gel formed through a sol-gel reaction of silicon alkoxide. The silica aero-gel is a material the volume of 90% or more of which is occupied by void and the remains are comprised of fine particles of SiO₂ having a diameter of several tens nm dendritically conglomerated, and since the particle diameter thereof is smaller than a wavelength of light, it has light-transparency and a refractive index of 1.2 or less. Furthermore, by varying the void ratio, the refractive index can be adjusted. Here, the refractive index of glass which is a material of substrate is 1.54 and the refractive index of quartz is 1.45. Furthermore, as the low refractive layer, SiO₂ film or other material such as polymer having the porosity may be used.

Furthermore, dry agent or chemical adsorbent may be dispersed in the material constituting the low refractive layer. By doing so, the sealing effect can be added to the low refractive layer.

FIG. 32 illustrates another example of the organic EL element.

In the respective examples described above, although it is described that the switching thin film transistor 142 has a so-called single gate structure, the present invention is not limited to it. That is, as shown in FIG. 32, the thin film transistor may have a double gate structure in which two gate electrodes 310, 311 are electrically connected to each other through a gate line not shown, or may have a so-called multi gate structure (a structure including a semiconductor film having two or more channel regions connected in series) such as triple gate structure or the like. The multi gate structure is advantageous for decreasing an off current value and is also advantageous for a large screen.

FIGS. 33(a) and 33(b) illustrate another example of a circuit in the organic EL display device.

The circuit shown in FIGS. 33(a) and 33(b) is a so-called current program type circuit for performing a power supply control of the EL element by controlling current. Furthermore, FIG. 32(a) employs a so-called current mirror circuit. By employing such circuit, the conduction state of the EL element can be maintained constantly to enable the EL layer to emit light stably. Furthermore, it is advantageous for constructing a large screen display device.

When a high-molecular light emitting material is used as the material for forming the light-emitting layer, although high molecules having a light emitting radical at its side chain is used, it is preferable that the high molecules having a conjugated structure at the main chain, particularly, polythiophene, poly-p-phenylene, polyarylene vinylene, polyfluorene and their derivatives be used. Among them, polyarylenevinylene and its derivative are preferable. The polyarylene vinylene and its derivative are preferably polymers comprising the repeat unit represented by the following chemical formula (1) by 50 mole % or more of total repeat units. It is more preferable that the repeat unit represented by the chemical formula 1 be 70 mole % or more of total repeat units though this may vary depending on the structure of the repeat unit.

—Ar—CR═CR′— (1)

[Here, Ar is an arylene radical or a heterocyclic compound radical, and R and R′ independently represent radicals selected from the group consisting of an organic radical having hydrogen and carbon number of 1 to 20, a perfluoro alkyl radical, and a cyano radical.]

The aforementioned high molecular light emitting material may comprise an aromatic compound radical or its derivatives, a heterocyclic compound radical or its derivatives, and a radical obtained by combining the aforementioned radicals, as repeat units besides the repeat unit represented by the chemical formula (1). Further, the repeat unit represented by the chemical formula (1) or other repeat units may be connected with non-conjugated units having ether radical, ester radical, amide radical and imide radical, and these non-conjugated portions may be included in the repeat unit.

The polyarylenevinylene includes PPV (poly(para-phenylenevinylene)) and PPV derivatives such as MO-PPV (poly(2,5-dimethoxy-1,4-phenylenvinylene)), a CN-PPV (poly(2,5-bishexyloxy-1,4-phenylene-(1-cynaovinylene))), an MEH-PPV (poly[2-methoxy-5-(2′-ethylhexyloxy)]-para-phenylenevinylene), etc., as represented by chemical formula (2).

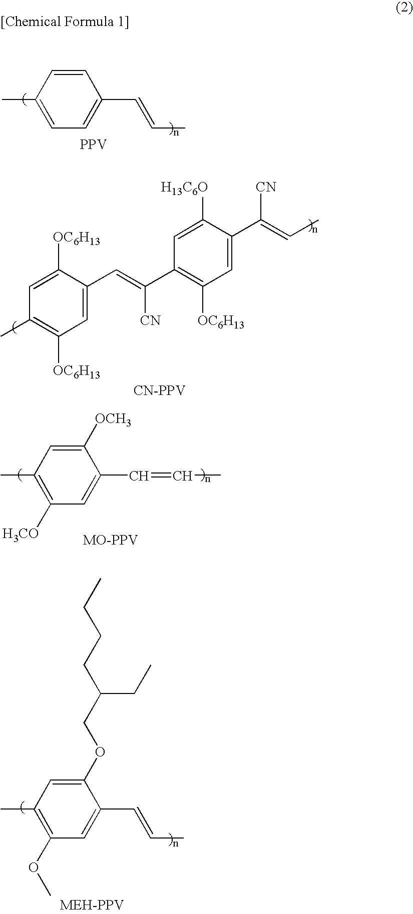

Besides the materials described above, for example, poly(paraphenylene), polyalkyl fluorene, etc. may be used, but, polyalkylfluorene as represented by chemical formula (3) (specifically, polyalkylfluorene base copolymer as represented by chemical formula (4)) is particularly preferable.

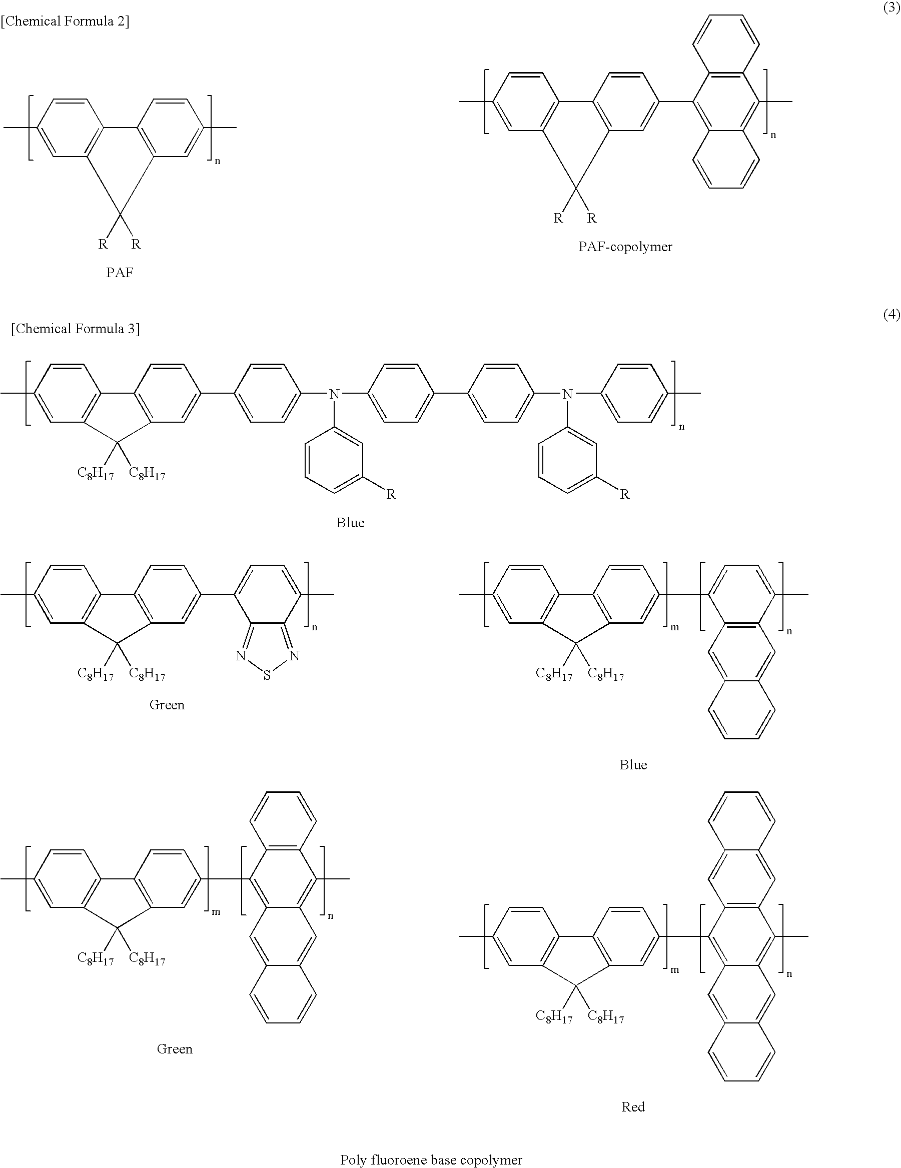

Furthermore, the high molecular light emitting material may be random, block or graft copolymers, and may be high molecules having intermediate structures thereof such as a block-like random copolymer. In view of obtaining a high molecular light emitting material having high quantum efficiency of light emitting, the block-like random copolymer and block or graft copolymers are more preferable than the perfect random copolymer. Furthermore, since the organic EL element formed herein uses the light emitted from thin films, the used high molecular light emitting material has high quantum efficiency of light emitting in solid states.

Among the aforementioned materials, the materials which is in a liquid state at the temperature when forming the light-emitting layer or the materials exhibiting a good solubility in a desired solvent can be used for forming the light-emitting layer by means of the inkjet method using a liquid material. As the solvent, for example, chloroform, methylenechloride, dichloroethane, tetrahydrofurane, toluene, xylene, etc. can be suitably used. Typically, 0.1 wt % or more of the high molecular light emitting materials can be dissolved in the solvents, although the solubility thereof depends on the structures of the high molecular light emitting materials and their molecular weights.

Furthermore, it is, in some cases, preferable that the molecule weights of the high molecular light emitting materials be 10³ to 10⁷ in terms of polystyrene, but oligomer having a molecular weight of 10³ or less can also be used.

By employing a synthesizing method corresponding to the desired high molecular light emitting material, the desired high molecular light emitting material can be obtained. For example, an exemplary method is a Wittig reaction from diphosphonate which are obtained from a dialdehyde compound where two aldehyde radicals are bonded to an arylene radical, a compound where two halogenated methyl radicals are bonded to an arylene radical, and a triphenylphosphine. Further, another synthesizing method includes a dehalogenation hydrogen method from a compound where two halogenated methyl radicals are bonded to an arylene radical. Further, another synthesizing method includes a sulfonide decomposition method where a sulfonide of a compound where two halogenated methyl radicals are bonded to an arylene radical is polymerized with an alkali, thereby obtaining an intermediate substance, and the obtained intermediate substance is heat-treated to obatin the aforementioned high molecular light emitting materials.

Furthermore, more specifically, the method of synthesizing arylenevinylene based copolymer which is one of the high molecular light emitting materials will be described. For example, in case of obtaining the high molecular light emitting materials using the Wittig reaction, the high molecular light emitting material comprising a phenylenevinylene radical and 2,5-dioxthyloxy-p-phenylenevinylene radical are obtained by means of the Wittig reaction where for example, firstly a bis(halogenated methyl) compound, more specifically, for example, 2,5-dioxthyloxy-p-xylylenedibromide is reacted with triphenylphosphine in an N,N-dimethylformamide solvent, thereby synthesizing phosphonate, and the phosphonate is condensed with a dialdehyde compound, more specifically, for example, terephthalaldehyde, for example in an ethylalcohol by using lithiumethoxyde. At that time, in order to obtain a copolymer, the two or more types of the diphosphonate and/or the two or more types of the dialdehyde compounds may be reacted.

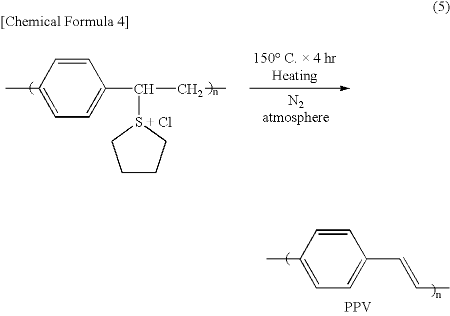

In the case that these high molecular light emitting materials are used as materials for forming the light-emitting layer, since their purities influence the light emitting characteristic, it is preferable that a purification process such as fractionation by a reprecipitation purification, chromatography, etc., be carried out after synthesization thereof.

When the high-molecular material is a material having a low solubility, for example, by applying a corresponding precursor and then thermally curing it, as represented by the chemical formula (5), a light-emitting layer may be obtained. For example, when the polyphenylene-vinylene is the high molecular light emitting material constituting the light-emitting layer, by arranging sulfonide of the corresponding precursor at portions where the light-emitting layer will be formed and then carrying out the heating process, the sulfonium radicals are eliminated to obtain the polyphenylene-vinylene serving as the light-emitting layer.

As the low-molecular material capable of constituting the light-emitting layer, materials emitting light in a visible range can be basically used. Among them, a material having an aromatic base substituent is suitable. For example, in addition to the conventionally-used material such as an alumiquinorinol complex (Alq₃), distyrylbiphenyl, BeBq₂ or Zn(OXZ)₂ as represented by chemical formula (6), a pyrazolinedimer, a quinoridinecarboxyl acid, a benzopyriliumperchrolate, a benzopiranoquinoridine, a rubrene, a phenanthroline-europium complex, etc. can be used.

By properly selecting materials emitting blue light, green light and red light from the high-molecular materials and the low-molecular materials represented above and arranging them at predetermined positions, a color display is possible.

When arranging them at the predetermined positions, the mask deposition method, the printing method, the inkjet method or the like can be used.

[Chemical Formula 5]

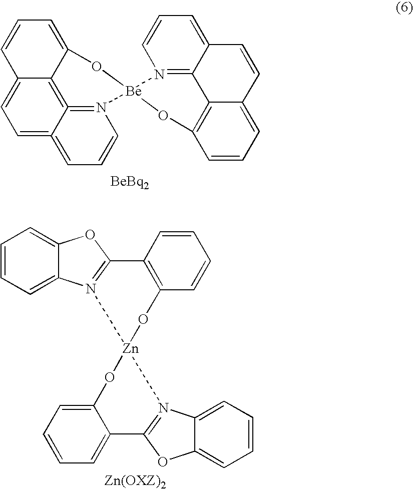

The light-emitting layer can be used as a so-called host/guest type light-emitting layer in which a host is dispersed in a guest serving as a medium.

In the host/guest type light-emitting layer, since a color emitted from the light-emitting layer is basically determined by the guest material, the guest material can be selected depending upon the desired emitted color. In general, a material efficiently emitting the fluorescent light is used. A material having an energy level higher than the level in the excited state associated with the light emitting of the guest material is basically suitable for the host material. Although the material having a high mobility of carriers may be required, in this case, the material can be selected from the aforementioned high molecular light emitting materials.

The guest material for emitting the blue light includes, for example, coronene, distyrylbiphenyl, etc., the guest material for emitting the green light includes, for example, quinacridone, rubrene, etc., the guest material for emitting the red light includes, for example, rhodamine, etc. as fluorescent pigment.

The host material can be properly selected depending upon the guest material. For example, by forming the light-emitting layer using Zn(OXZ)₂ and coronene as the host material and the guest material, respectively, the light-emitting layer emitting the blue light can be obtained.

A phosphorescent material can be also used as the guest material. For example, Ir(ppy)₃, Pt(thpy)₂, PtOEP, etc. represented by chemical formular (7) can be suitably used.

[Chemical Formula 6]

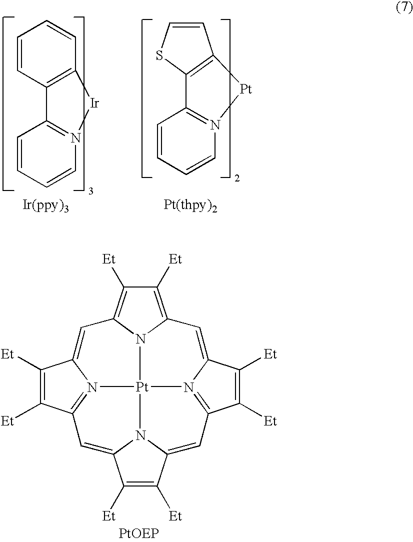

Furthermore, when the phosphorescent material represented by the chemical formula (7) is used as the guest material, for example, CBP, DCTA, TCPB, Alq₃, etc. represented by the chemical formula (8) can be suitably used as the host material.

Furthermore, the host/guest type light-emitting layer may be formed by means of a co-deposition method or a method for applying a material obtained by liquidizing the host material and the guest material or their precursors, etc.

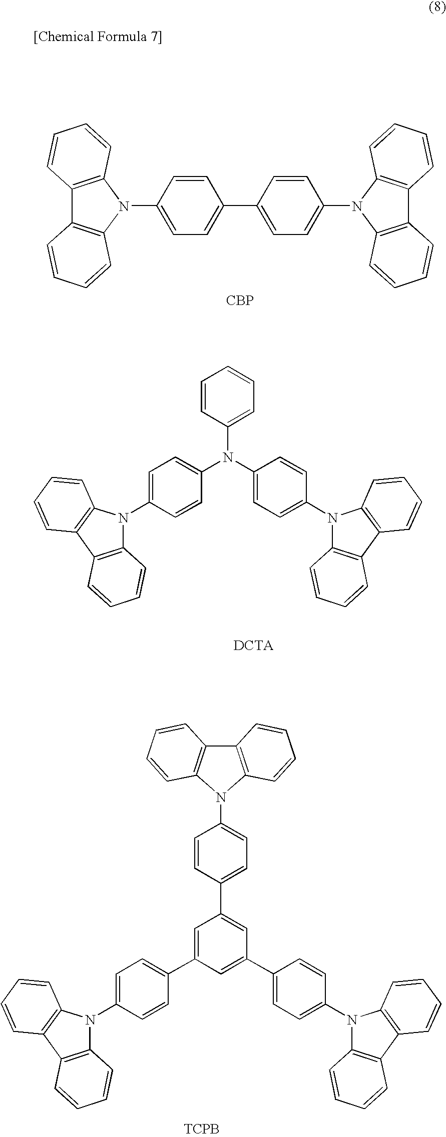

Furthermore, in the aforementioned examples, although the hole-transporting layer is formed as a lower layer of the light-emitting layer and the electron-transporting layer is formed as an upper layer thereof, the present invention is not limited to it. For example, only any one of the hole-transporting layer and the electron-transporting layer may be formed, the hole-injecting layer may be formed in place of the hole-transporting layer, and only the light-emitting layer may be formed independently.

Furthermore, in addition to the hole-injecting layer, the hole-transporting layer, the light-emitting layer and the electron-transporting layer, a hole blocking layer may be formed, for example, on a counter electrode side of the light-emitting layer, to accomplish the long life span of the light-emitting layer. As a material for forming the hole blocking layer, for example, BCP shown in the chemical formula (9) or BAlq shown in the chemical formula (10) can be used, but BAlq is more preferable from the point of view of a long life span.

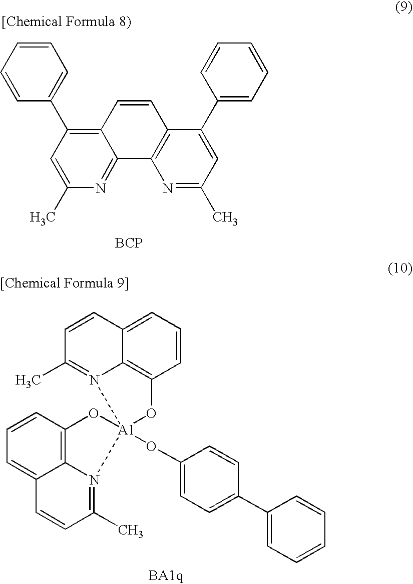

Further, the electro-optical device of the present invention is not limited to the aforementioned organic EL display device, and can apply to other electro-optical device. Such electro-optical device includes, for example, various display devices such as a liquid crystal display device.

Furthermore, the film-forming apparatus and the material arranging method according to the present invention are not limited to use in manufacturing the electro-optical device, and can be also used for processes of manufacturing the electronic device such as the semiconductor element, the color filter, etc. For example, as the electronic device, semiconductor elements such as transistors, specifically, organic transistors the semiconductor layer of which is made of an organic material, or memory elements such as FeRAM (Ferroelectric Random Access Memory), MRAM Magnetic Random Access Memory), etc. can be suitably used. Furthermore, the color filter obtained from such materials may transmit a desired color and may emit a desired color light. By manufacturing the electronic device such as the color filter using the film-forming apparatus of the present invention, the degree of freedom in selection of materials is high and thus optimization of the structure can be accomplished. For this reason, it is easy to accomplish a long life span, a high quality, a high functionality, etc.

[Sixth Embodiment]

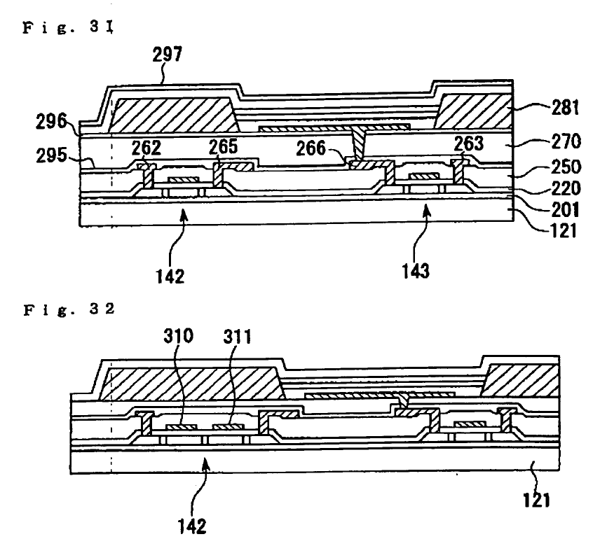

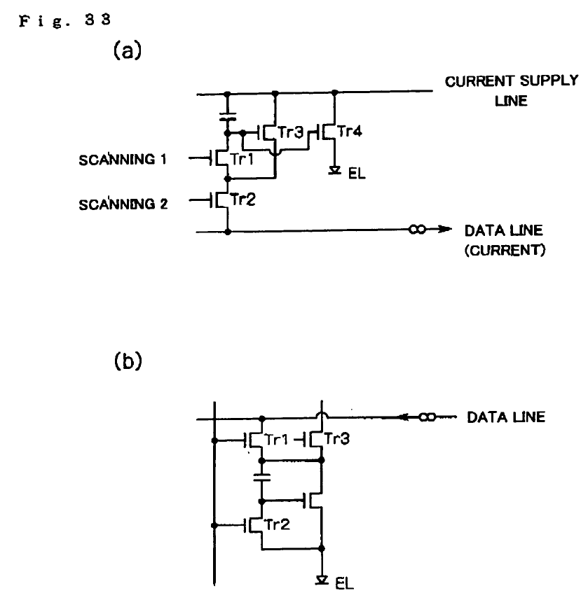

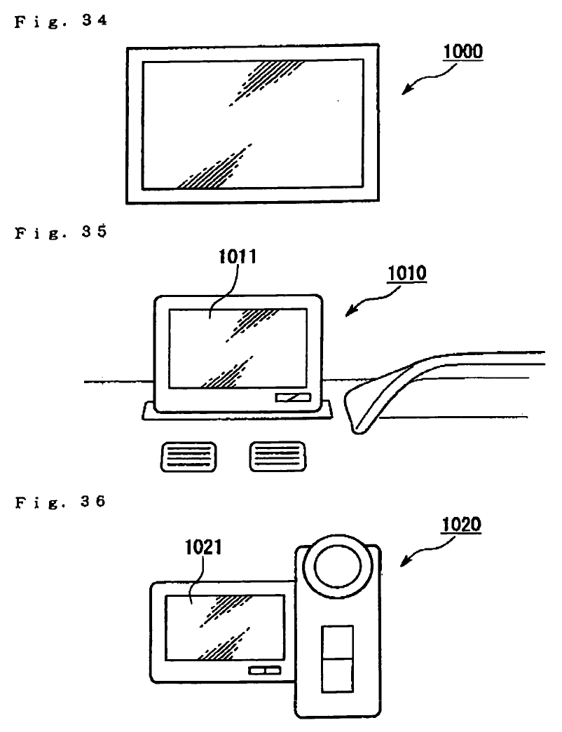

FIGS. 34 to 39 show examples of an electronic apparatus of the present invention.

The electronic apparatuses of these examples comprise the electro-optical device of the present invention such as the aforementioned organic EL display device or the like as a display means.

FIG. 34 shows an example of a display device for displaying television images, or characters or images transmitted through a computer. In FIG. 34, the reference numeral 1000 denotes a main body of the display device employing the electro-optical device of the present invention. Further, the main body 1000 of the display device can cope with a large screen by using the aforementioned organic EL display device.

Furthermore, FIG. 35 shows an example of a car navigation device. In FIG. 35, the reference numeral 1010 denotes a main body of the navigation device, and the reference numeral 1011 denotes a display unit (display means) employing the electro-optical device of the present invention.

Furthermore, FIG. 36 shows an example of a portable image-recording device (video camera). In FIG. 36, the reference numeral 1020 denotes a main body of the recording device, and the reference numeral 1021 denotes a display unit employing the electro-optical device of the present invention.

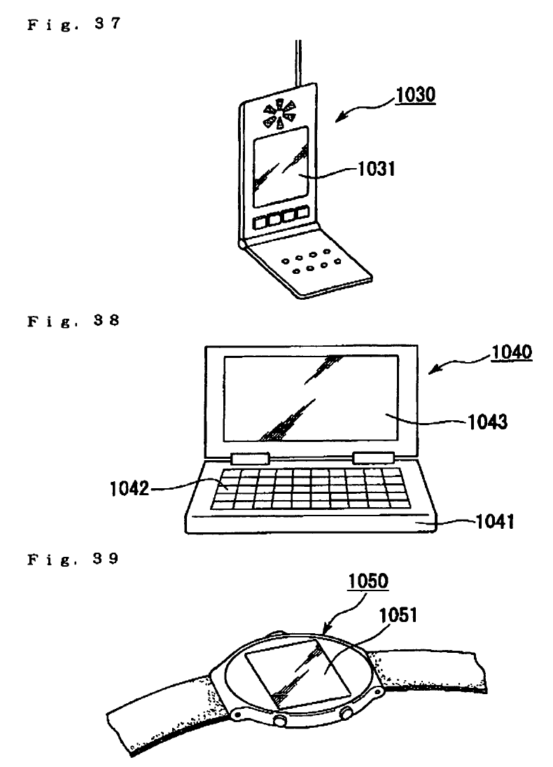

Furthermore, FIG. 37 shows an example of a portable phone. In FIG. 37, the reference numeral 1030 denotes a main body of the portable phone, and the reference numeral 1031 denotes a display unit (display means) employing the electro-optical device of the present invention.

Furthermore, FIG. 38 shows an example of an information processing device such as a word processor, a personal computer or the like. In FIG. 38, the reference numeral 1040 denotes the information processing device, the reference numeral 1041 denotes a main body of the information processing device, the reference numeral 1042 denotes an input unit such as a keyboard, and the reference numeral 1043 denotes a display unit employing the electro-optical device of the present invention.

Furthermore, FIG. 39 shows an example of a wrist watch type electronic apparatus. In FIG. 39, the reference numeral 1050 denotes a main body of the wrist watch, and the reference numeral 1051 denotes a display unit employing the electro-optical device of the present invention.

Since the electronic apparatuses shown in FIGS. 34 to 39 comprise the electro-optical device of the present invention as the display means, it is possible to realize a display excellent in durability and quality.

Until now, although proper embodiments according to the present invention are described with reference to the appended drawings, the present invention is not limited to these embodiments, of course. Various shapes or combinations, etc of the respective element members described in the aforementioned embodiments are only examples, and thus various modifications can be made depending upon design requests, etc. within a range not departing from the subject matter of the present invention.

[Advantages]

According to the material arranging method and the film-forming apparatus of the present invention, since the degree of freedom in selection of material is high, it is thus possible to arrange various materials such as high-molecular materials or low-molecular materials on the base, and also, it is possible to decrease disadvantages due to residual of solvent. Furthermore, by controlling the pressure of the inside of the processing chamber, it is possible to discharge materials at molecular levels from the nozzles, and as a result, it is possible to form a material film having much higher purity, or the material film the thickness of which is controlled with a high accuracy, or a functional film having a specific function. Furthermore, by rapidly detecting the ejection failure of the nozzles, it is possible to decrease the defectives, and by performing the preliminary ejection, it is possible to always stabilize the ejection condition of materials. That is, by detecting the ejection failure of the nozzles before arranging the material in the patterning area on the base, a plurality of defectives are prevented from being manufactured, so that it is possible to enhance the production yield of products.

According to the electro-optical device and its manufacturing method of the present invention, it is possible to provide an electro-optical device capable of accomplishing a long life span, a high quality, and a high functionality. Furthermore, it is possible to enhance the production yield of the device.

According to the electronic device of the present invention, it is possible to accomplish a long life span, a high quality, and a high functionality. Furthermore, it is possible to enhance the production yield of the device.

According to the electronic apparatus of the present invention, it is possible to accomplish a long life span, a high quality, and a high functionality of display means. Furthermore, it is possible to accomplish a low cost due to enhancement of the production yield of the elements.

What is claimed is:

1. A material arranging method of arranging a material on a base, the method comprising:
an ejection step of ejecting the material from at least one nozzle toward a predetermined area of the base, which is provided in a vacuum atmosphere that is adjusted to a high degree of vacuum; and
a detection step of detecting an ejection failure of a nozzle in the vacuum atmosphere before starting the ejection step.

2. A material arranging method of arranging a material on a base, the method comprising:
an ejection step of ejecting the material from at least one nozzle toward a predetermined area of the base, which is provided in a vacuum atmosphere that is adjusted to a pressure of 10⁻³ torr or less; and
a detection step of detecting an ejection failure of a nozzle in the vacuum atmosphere before starting the ejection step.

3. A material arranging method of arranging a material on a base, the method comprising:
an ejection step of ejecting the material from at least one nozzle toward a predetermined area of the base, which is provided in a vacuum atmosphere that is adjusted to a pressure of 10⁻⁵ torr or less; and
a detection step of detecting an ejection failure of a nozzle in the vacuum atmosphere before starting the ejection step.

4. The material arranging method according to claim 1, wherein the detection step includes an action of ejecting the material to a preliminary-ejecting area other than the predetermined area and detecting the ejection failure of a nozzle on the basis of the ejecting result.

5. The material arranging method according to claim 1, wherein the detection step includes an action of providing a preliminary member in the predetermined area, ejecting the material to a preliminary-ejecting area provided in the preliminary member, and detecting the ejection failure of a nozzle on the basis of the ejection result.

6. A material arranging method according to claim 4, wherein the detection of the ejection failure of a nozzle is performed by detecting the light-reflectivity of the material ejected to the preliminary-ejecting area.

7. The material arranging method according to claim 4, wherein the detection of the ejection failure of the at least one nozzle is performed by detecting the light-transmissivity of the material ejected to the preliminary-ejecting area.

8. The material arranging method according to claim 1, wherein the detection step is performed at the time of changing of the material in the ejection step.

9. A material arranging method of arranging a material on a base, the method comprising:
an ejection step of ejecting the material from at least one nozzle toward a predetermined area of the base, which is provided in a vacuum atmosphere that is adjusted to a high degree of vacuum; and
a preliminary ejection step of preliminarily ejecting the material from a nozzle toward an area on the base other than the predetermined area before starting the ejection step.

10. A material arranging method of arranging a material on a base, the method comprising:
an ejection step of ejecting the material from at least one nozzle toward a predetermined area of the base, which is provided in a vacuum atmosphere that is adjusted to a pressure of 10⁻³ torr or less; and
a preliminary ejection step of preliminarily ejecting the material from a nozzle toward an area on the base other than the predetermined area before starting the ejection step.

11. A material arranging method of arranging a material on a base, the method comprising:
an ejection step of ejecting the material from at least one nozzle toward a predetermined area of the base, which is provided in a vacuum atmosphere that is adjusted to a pressure of 10−5 torr or less; and
a preliminary ejection step of preliminarily ejecting the material from a nozzle toward an area on the base other than the predetermined area, before starting the ejection step.

12. A material arranging method according to claim 9, wherein the preliminary ejection step performs the preliminary ejection of the nozzle in a process immediately previous to the ejection step.

13. A material arranging method according to claim 9, wherein the preliminary ejection step is performed at the time of changing the material in the ejection step.

14. The material arranging method according to claim 9, further comprising a positional correction step of detecting an arranged position of the material arranged through the preliminary ejection and a target position to arrange the material through the preliminary ejection right after the preliminary ejection step, and performing a positional correction of a nozzle when a positional deviation occurs between the arranged position and the target position.

15. A method of manufacturing an electronic device, wherein at least some elements constituting the electronic device are formed using the material arranging method according to claim 1.

16. The method of manufacturing an electronic device according to claim 15, wherein a material for forming at least one of a conductive layer, a semiconductor layer, and an insulating layer constituting a transistor or a memory element is arranged as the material, and then the conductive layer, the semiconductor layer, or the insulating layer is formed.

17. The method of manufacturing an electronic device according to claim 15, wherein patterns for separating wires from each other are formed in advance on the base, the forming material is arranged in the patterns, and then the conductive layer is formed.

18. A method of manufacturing an electro-optical device, wherein at least some elements constituting the electro-optical device are formed using the material arranging method according to claim 1.

19. The method of manufacturing an electro-optical device according to claim 18, wherein a material for forming at least one of an electron-transporting layer, a hole-transporting layer, a light-emitting layer, and electrodes constituting an organic electroluminescent element is arranged as the material, and then the electron-transporting layer, the hole-transporting layer, the light-emitting layer, or the electrodes is formed.

20. The method of manufacturing an electro-optical device according to claim 18, wherein partitions for separating pixels from each other are formed in advance on the base, the forming material is arranged in the partitions, and then the electron-transporting layer, the hole-transporting layer, or the light-emitting layer is formed.

21. A film-forming apparatus comprising:
a processing chamber;
a pressure control system for controlling the pressure in the processing chamber to a low pressure;
at least one nozzle provided in the processing chamber and connected to a material supply source, for arranging a material on a member provided in the processing chamber;
a stage provided in the processing chamber for holding the member;
moving means for relatively moving the position of the nozzle or the stage; and
inspecting means for inspecting the material arranged on the member.

22. A film-forming apparatus comprising:
a processing chamber;
a pressure control system for controlling the pressure in the processing chamber to a low pressure;
a head having a plurality of nozzles provided in the processing chamber and connected to a material supply source, for arranging a material on a member provided in the processing chamber;
a stage provided in the processing chamber for holding the member;
moving means for relatively moving the position of the nozzles or the stage; and
inspecting means for inspecting the material arranged on the member.

23. The film-forming apparatus according to claim 21, wherein the member is a base having a predetermined area in which a film of the material is formed.

24. The film-forming apparatus according to claim 21, wherein the member is a preliminary member having a preliminary-ejecting area.

25. The film-forming apparatus according to claim 21, wherein the nozzles further comprise a preliminary nozzle to be used in place of a nozzle having an ejection failure, when the ejection failure occurs in one of the nozzles.

26. The film-forming apparatus according to claim 21, wherein the inspecting means comprises detecting means for detecting an ejection failure of the nozzles on the basis of an ejecting result of the material.

27. The film-forming apparatus according to claim 21, wherein the inspecting means further comprises position correcting means for detecting an arranged position of the material and a target position to arrange the material and performing a positional correction of the nozzles when a positional deviation occurs between the arranged position and the target position.

28. An electronic device manufactured using the film-forming apparatus according to claim 21.

29. An electro-optical device manufactured using the film-forming apparatus according to claim 21.

30. An electronic apparatus comprising the electro-optical device according to claim 29 as a display means.
